(19) United States
(12) Patent Application Publication
(10) Pub. No.: US 2009/0320921 A1
(43) Pub. Date: Dec. 31, 2009

(54) Photovoltaic Glazing Assembly and Method

(76) Inventors: Robert C. Grommesh, St. Louis Park, MN (US); Richard A. Palmer, Delano, MN (US); Roger D. O'Shaughnessy, Wayzata, MN (US); Benjamin J. Zurn, Roseville, MN (US); Curt Queck, Spring Ggreen, WI (US)

Correspondence Address: INTELLECTUAL PROPERTY GROUP;FREDRIKSON & BYRON, P.A., 200 SOUTH SIXTH STREET, SUITE 4000, MINNEAPOLIS, MN, 55402, US

(21) Appl. No.: 12/536,388

(22) Filed: Aug. 5, 2009

Related U.S. Application Data
(63) Continuation-in-part of application No. 12/337,441, filed on Dec. 17, 2008.
Application No. 12/337,441 is a continuation-in-part of application No. 12/167,826, filed on Jul. 3, 2008.
Application No. 12/167,826 is a continuation-in-part of application No. 12/337,853, filed on Dec. 18, 2008.
Application No. 12/337,853 is a continuation-in-part of application No. 12/180,018, filed on Jul. 25, 2008.
(60) Provisional application No. 61/043,908, filed on Apr. 10, 2008.
(60) Provisional application No. 61/025,422, filed on Feb. 1, 2008.

(51) Int. Cl. H01L 31/00; H01L 21/50

(52) U.S. Cl. 136/256; 438/64; 257/E21.499

(57) ABSTRACT

A photovoltaic glazing assembly including first and second substrates, at least one being formed of a light transmitting material. The assembly includes a photovoltaic coating over at least the central region of a surface of the first substrate or the second substrate. In some embodiments, a seal system encloses a gas space between the substrates and optionally has a thickness of between approximately 0.01 inch and approximately 0.1 inch. Certain embodiments provide a flexible and electrically non-conductive retention film over the photovoltaic coating. Additionally or alternatively, the assembly can have a peripheral seal system with relative dimensions in certain ranges. Advantageous manufacturing methods are also provided.

### PRIORITY CLAIM

This application is a continuation-in-part of U.S. application Ser. No. 12/337,441, filed on Dec. 17, 2008, which is a continuation-in-part of U.S. application Ser. No. 12/167,826, filed on Jul. 3, 2008, which claims priority to U.S. Provisional Application Ser. No. 61/043,908, filed on Apr. 10, 2008, the contents of each of which are hereby incorporated by reference. This application is also a continuation-in-part of U.S. application Ser. No. 12/337,853, filed on Dec. 18, 2008, which is a continuation-in-part of U.S. application Ser. No. 12/180,018, filed on Jul. 25, 2008, which claims priority to U.S. Provisional Application Ser. No. 61/025,422, filed on Feb. 1, 2008, the contents of each of which are hereby incorporated by reference.

### TECHNICAL FIELD

The present invention pertains to photovoltaic assemblies and more particularly to photovoltaic assemblies that include at least two substrates spaced apart from each other on either side of a gas space.

### BACKGROUND

Photovoltaic devices are used to convert solar radiation into electrical energy. There are a variety of photovoltaic devices, and they commonly fall into two basic categories, either bulk or thin film.

Bulk photovoltaic devices and bulk technologies are often referred to as “wafer-based.” Typically, self-supporting wafers between 180 to 350 micrometers thick are processed and then joined together to form a solar cell module. The most commonly used bulk material is silicon, more specifically crystalline silicon (“c-Si”). The various materials and methods used in manufacturing conventional bulk photovoltaic devices are well-documented and known to those skilled in the art.

Thin film photovoltaic devices and thin film technologies have generally been developed with the goals of reducing the amount of radiation-absorbing material used or reducing the size of the device. More recently, attention has been focused increasingly on enhancing the efficiency and decreasing the cost of photovoltaic devices. The adoption of photovoltaic devices as an energy source has been limited, in large part due to cost considerations.

### SUMMARY OF THE INVENTION

Embodiments of the invention include a photovoltaic glazing assembly. In some embodiments, the photovoltaic glazing assembly includes a first substrate formed of a light transmitting material and a second substrate. The first and second substrates each have first and second major surfaces. Each second surface has a central region and a periphery, and the second surfaces face each other. In some embodiments, the two substrates are generally parallel to each other.

The photovoltaic glazing assembly includes a photovoltaic coating over at least a central region of the second surface of the first or second substrate. The photovoltaic coating commonly will be temperature sensitive, e.g., such that the photovoltaic efficiency decreases with increasing temperature.

The photovoltaic glazing assembly includes a seal system, which preferably has contiguous inner and outer seals each extending between (e.g., from one to the other of) the second surfaces of the two substrates, so as to seal the first and second substrates to one another along their peripheries. The seal system bounds a narrow gas space between the two substrates. In certain preferred embodiments, the gas space has a thickness T of between approximately 0.01 inch and approximately 0.1 inch to facilitate heat transfer across the gas space. This heat transfer prevents some efficiency loss because it keeps the temperature of the photovoltaic coating lower.

In some embodiments, the inner seal has a width W₁ (e.g., measured inwardly from the edge of the panel, parallel to the second surfaces) and a thickness t that provide a W₁/t ratio of at least 2. Such embodiments are useful for isolating the narrow air space from the exterior environment, thereby limiting gas transfer between the gas space and the exterior environment.

Certain embodiments of the invention provide a photovoltaic glazing assembly including a first substrate, optionally formed of a light transmitting material, and a second substrate, each of the first and second substrates having first and second major surfaces, each second surface having a central region and a periphery, and the second surfaces facing each other. Preferably, the second surfaces are generally parallel to each other. In the present embodiments, a temperature-sensitive photovoltaic coating is over at least the central region of the second surface of the first substrate or the second substrate. The photovoltaic coating is characterized by a photovoltaic efficiency that decreases with increasing temperature. In the present embodiments, a gas space is located between the first and second substrates and has a thickness T of between 0.01 inch and 0.095 inch to facilitate heat transfer across the gas space so as to restrain loss of photovoltaic efficiency due to temperature increases of the photovoltaic coating. Preferably, the gas space is the glazing assembly's only interpane space. In the present embodiments, a peripheral seal system is located between the first and second substrates and comprises contiguous first and second seals, each connecting the first and second substrates together along their peripheries. Preferably, the first seal has a width W₁ and a thickness t that provide a W₁/t ratio of at least 2.

Further, some embodiments provide a method for making a photovoltaic glazing assembly. For example, the method can comprise providing a first substrate and a second substrate, the first and second substrates each having first and second major surfaces, the second surfaces each having a central region and a periphery. In the present method, at least one of the substrates preferably is transparent. A temperature-sensitive photovoltaic coating is on at least the central region of the second surface of the first or second substrate, and this photovoltaic coating is characterized by a photovoltaic efficiency that decreases with increasing temperature. The present method includes applying a first seal to the periphery of at least one of the substrates, such that the first seal is spaced from the edge of that substrate. The method also includes bringing the first and second substrates together in an opposed relationship such that the first seal is between the peripheries of the second surfaces of the first and second substrates, and applying pressure until a gas space between the first and second substrates has a thickness T of less than 0.095 inch so as to facilitate heat transfer across the gas space and thereby restrain loss of photovoltaic efficiency due to temperature increases of the photovoltaic coating. Thereafter, the method includes applying a second seal into a peripheral channel defined collectively by the first seal and peripheral regions of the second surfaces of the first and second substrates. Preferably, the second seal is contiguous to the first seal such that there are substantially no air spaces between the first and second seals.

Some embodiments provide a photovoltaic glazing assembly including first and second substrates each having first and second major surfaces, each second surface having a central region and a periphery, where the second surfaces face each other. Preferably, at least one of the first and second substrates is formed of a light transmitting material. In the present embodiments, a temperature-sensitive photovoltaic coating is over at least the central region of the second surface of the first substrate or the second substrate, and this photovoltaic coating is characterized by a photovoltaic efficiency that decreases with increasing temperature. In the present embodiments, a flexible and electrically non-conductive retention film is over the photovoltaic coating. The retention film in the present embodiments has a thickness of less than 0.009 inch and yet has a tear strength combined with a flexibility that hold the photovoltaic coating together with the underlying substrate in case that substrate is fractured. Further, the present embodiments include a gas space located between the first and second substrates, and the gas space has a thickness T of between 0.01 inch and 0.09 inch to facilitate heat transfer across the gas space so as to restrain loss of photovoltaic efficiency due to temperature increases of the photovoltaic coating. Preferably, an exposed surface of the retention film bounds the gas space. Finally, the assembly includes a seal system (between the first and second substrates) joining the first and second substrates to each other along their peripheries.

Other embodiments provide a method for making a photovoltaic glazing assembly. The present method comprises providing a first substrate and a second substrate, the first and second substrates each having first and second major surfaces, and the second surfaces each having a central region and a periphery. Preferably, at least one of the substrates is transparent, and a photovoltaic coating is on at least the central region of the second surface of the first or second substrate. The present method includes applying a ribbon comprising side-by-side first and second seals to the periphery of at least one of the second surfaces, such that when initially applied the ribbon has a thickness t that is greater adjacent to a midpoint of the ribbon than adjacent to sides of the ribbon. The method also includes bringing the first and second substrates together in an opposed relationship such that the ribbon is between the peripheries of the second surfaces of the first and second substrates, and applying pressure so as to move the first and second substrates closer together until the thickness t of the ribbon is at least substantially uniform from the midpoint to the sides of the ribbon.

In certain embodiments, the invention provides a photovoltaic glazing assembly comprising first and second substrates each having first and second major surfaces, each second surface having a central region and a periphery, and the second surfaces facing each other. Preferably, at least one of the first and second substrates is formed of a light transmitting material. A photovoltaic coating is over at least the central region of the second surface of the first substrate or the second substrate. In the present embodiments, a flexible and electrically non-conductive retention film is over the photovoltaic coating, and the retention film can optionally have a thickness of less than 0.006 inch while still having a tear strength combined with a flexibility that hold the photovoltaic coating together with the underlying substrate in case that substrate is fractured. A gas space is located between the first and second substrates, and an exposed surface of the retention film preferably bounds the gas space. A seal system between the first and second substrates joins the first and second substrates to each other along their peripheries.

### BRIEF DESCRIPTION OF THE DRAWINGS

The following drawings are illustrative of particular embodiments of the invention and therefore do not limit the scope of the invention. The drawings are not necessarily to scale (unless so indicated) and are intended for use in conjunction with explanations in the following detailed description. Embodiments of the invention will hereinafter be described in conjunction with the appended drawings, wherein like numerals denote like elements.

FIG. 1 is a perspective view of a photovoltaic assembly according to some embodiments of the present invention.

FIG. 2 is a plan view of either of the substrates of the assembly shown in FIG. 1.

FIG. 3 is a perspective view of a portion of the assembly shown in FIG. 1, according to some embodiments of the invention.

FIG. 3A is a cross sectional view of a photovoltaic assembly in accordance with certain embodiments of the invention.

FIGS. 4 and 5 are section views through line A-A of FIG. 1, according to different embodiments of the invention.

FIG. 6A is a perspective view of a nozzle useful for applying a second seal to a photovoltaic glazing assembly according to some embodiments of the invention.

FIG. 6B is a side view of the nozzle of FIG. 6A.

FIG. 6C is a broken-away cross sectional view of a photovoltaic glazing assembly in accordance with some embodiments of the invention.

FIG. 6D is a rear view of a portion of a photovoltaic glazing assembly in accordance with certain embodiments of the invention.

FIG. 6E is a broken-away cross sectional view of a photovoltaic glazing assembly in accordance with embodiments of the invention.

FIG. 7A is a cross sectional view of a portion of a coated substrate of a photovoltaic assembly in accordance with certain embodiments of the invention.

FIG. 7B is a perspective view of a photovoltaic assembly in accordance with certain embodiments of the invention.

FIG. 8A-8D are perspective views of a portion of a photovoltaic assembly in accordance with certain embodiments of the invention.

FIG. 9A-9D are perspective views of a portion of a photovoltaic assembly in accordance with certain embodiments of the invention.

FIG. 10 is a cross sectional view of a partially formed assembly according to some embodiments of the invention.

FIGS. 10A-10D are partially broken-away cross sectional views illustrating methods for manufacturing a photovoltaic assembly in accordance with certain embodiments of the invention.

FIG. 10E is a partially broken-away perspective view of the photovoltaic assembly of FIG. 10D.

FIGS. 10F and 10G are partially broken-away cross sectional views of photovoltaic assemblies according to some embodiments of the invention.

FIG. 11 is a partially broken-away cross sectional view of a photovoltaic assembly according to some embodiments of the invention.

FIG. 12 is a process flow schematic showing application of a retention film according to some embodiments of the invention.

FIG. 13 is a perspective schematic view of a desiccant application apparatus according to some embodiments of the invention.

FIG. 14 is a graph of simulated temperatures at the photovoltaic coating for different gas space thicknesses.

FIGS. 15A-15C illustrate methods for manufacturing a photovoltaic assembly in accordance with certain embodiments of the invention.

### DETAILED DESCRIPTION

The following detailed description and figures are exemplary in nature and are not intended to limit the scope, applicability, or configuration of the invention in any way. Rather, the following description and figures provide practical illustrations for implementing exemplary embodiments of the present invention.

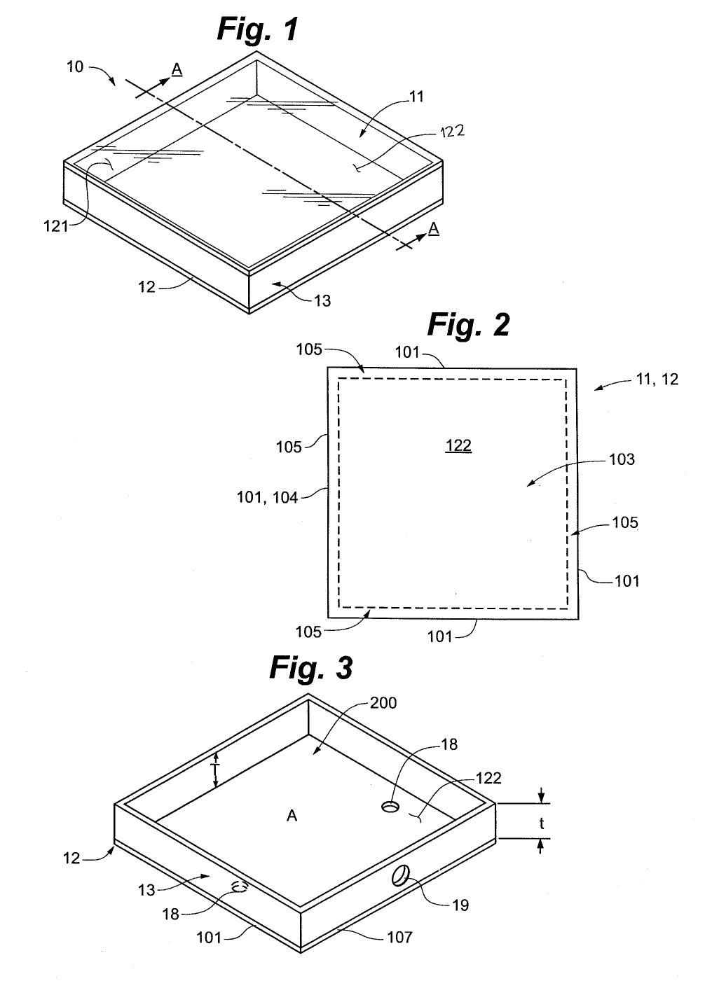

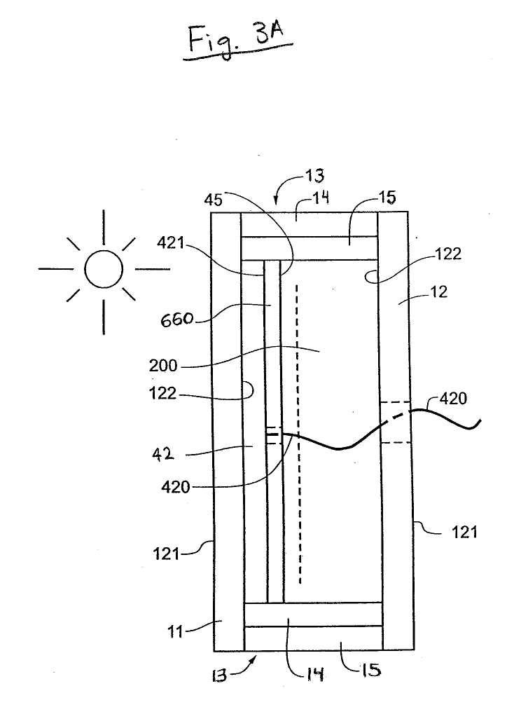

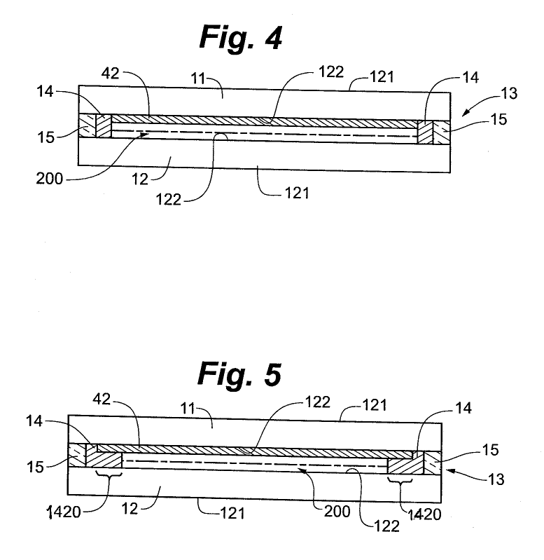

FIG. 1 is a perspective view of a photovoltaic assembly 10 according to some embodiments of the invention. FIG. 1 shows the assembly 10 including a first pane, or substrate 11, a second pane, or substrate 12 and a sealing system 13, which is between the first 11 and second 12 substrates and joins (e.g., seals) them together. The first (or “exterior”) major surfaces 121 of the substrates 11, 12 face outward (away from each other), and the second (or “interior”) major surfaces 122 face inward (toward each other). Thus, the illustrated substrates 11, 12 are spaced apart from each other by the seal system 13. The seal system 13 in FIG. 1 is shown schematically for ease of illustration; its relative thickness and width are not representative of preferred embodiments. In the embodiment illustrated, the two substrates are generally parallel to each other. The first and second surfaces 121, 122 of each substrate 11, 12 can be more clearly seen, for example, in FIGS. 3A, 4, 5 and 6C. The illustrated seal system 13 comprises a first seal 14 and a second seal 15. Embodiments of such seals 14, 15 can also be seen in FIGS. 4, 5, 9, 10, 10A-10E and 11. In alternate embodiments, the seal system 13 has only one seal, or it has more than two seals.

According to the illustrated embodiment, the first substrate 11, second substrate 12, or both are transparent or light transmitting. For example, one or both substrates can be formed from glass or a plastic material, such as polycarbonate. When glass is used, it can optionally be a high-transmittance, low color silica-based glass having a relatively low iron content compared to the glass typically used for fenestration products. In some cases, the total iron content range is between about 0.04 weight percent and 0.07 weight percent. Further, the glass may be oxidized to convert some ferrous iron to ferric iron, which further reduces the color and increases the transmittance of the glass. Certain embodiments employ such glass for at least the front substrate.

Depending on which first surface 121 faces generally toward the sun (or is the “active” surface), the corresponding substrate is formed of a transparent or light transmitting material. The other substrate may be similarly formed, according to some embodiments, but can alternatively be tinted, translucent, or opaque according to some alternate embodiments (or may be provided with an opacifier layer). In other words, it need not have the same light transmitting properties (or be formed of the same material) as the “front” substrate (which defines a #1 surface, i.e., the major surface through which solar radiation entering the glazing assembly first passes). It is to be understood that the illustrated embodiments of the assembly 10 can have reversed arrangements or orientations, in that, depending on which is the front side (the “radiation-incident side”) of the photovoltaic coating 42 (and depending on which substrate has the photovoltaic coating), either the first substrate 11 or the second substrate 12 can have its first surface 121 facing generally toward the sun or other source of radiation.

Although the term “glazing” may connote glass, the use of that term is not so limited in the present disclosure. Rather, the photovoltaic assemblies of the present invention can incorporate any transparent or light transmitting substrate, including glass or plastic such as polycarbonate, for use as one or both substrates, 11, 12. Further, while the illustrated embodiments are generally square or rectangular, it is to be understood that assemblies according to the invention are not limited to the illustrated shapes and, in fact, can take a variety of shapes, including, but not limited to polygonal, circular, semi-circular, oblong and the like.

In certain embodiments, the substrate 11, 12 on which the photovoltaic coating 42 is provided is tempered glass and yet the assembly 10 is still provided with a retention film 660 over the photovoltaic coating. Conventional wisdom may suggest that a retention film is not needed when tempered glass is used. However, some processing of photovoltaic panels may involve temperatures high enough to alter the balanced internal stresses of tempered glass, effectively “un-doing” the temper. Thus, certain embodiments provide the retention film 660 even though the coated substrate 11/12 is tempered glass.

FIG. 2 is a schematic plan view of either of the substrates 11, 12. FIG. 2 illustrates the second major surface 122 of substrate 11/12 having edges 101, as well as a central region 103 and a periphery 105, which are delineated from one another by the dashed line. Here, the periphery 105 entirely surrounds the central region 103, although this may not always be the case. With reference to FIGS. 1 and 2, and in conjunction with FIG. 3 (which is a perspective view showing the first substrate 11 removed), it can be appreciated that the seal system 13 joins the first substrate 11 to the second substrate 12 along at least a portion of (optionally entirely about) the periphery 105 of each substrate. When both substrates 11, 12 are of the same size and dimensions, they can be joined together with their peripheries 105 and edges 101 aligned. However, in some embodiments, the substrates 11, 12 may be joined together without their peripheries or edges aligned. This may be due to the substrates 11, 12 having different dimensions, such that when joined together by the seal system 13, their peripheries are not aligned (e.g., their edges may not be aligned due to a size differential, such as one substrate being undersized, in at least one dimension, relative to the other). Thus, the phrase “along the periphery” or “along their peripheries” and similar references to the relationship between the peripheries of the substrates 11, 12 should be understood to include the peripheries being in an overlapping relationship as well as the peripheries 105 and/or the edges 101 of the substrates being aligned.

The assembly 10 includes a photovoltaic coating 42 over (e.g., on) at least a central region 103 of the second surface 122 of the first or second substrate. In some embodiments, the assembly 10 is configured (e.g., the photovoltaic coating is positioned) such that solar radiation is to first enter the assembly through the substrate bearing the photovoltaic coating. Reference is made to FIG. 3A.

The coating 42 can be a bulk photovoltaic element (e.g., a wafer) or a thin film photovoltaic coating. It is contemplated and is to be understood that the photovoltaic coating can be of any type known to those skilled in the art.

Materials used in the photovoltaic coating may include cadmium sulfide, cadmium telluride, copper-indium selenide, copper indium/gallium diselenide, gallium arsenide, organic semiconductors (such as polymers and small-molecule compounds like polyphenylene vinylene, copper phthalocyanine, and carbon fullerenes) and thin film silicon. Suitable film thicknesses, layer arrangements, and deposition techniques are well known for such layers. The coating can include one or more of the following: a sodium ion diffusion barrier layer, a TCO layer, and a buffer layer. Suitable materials, film thicknesses, layer arrangements, and deposition techniques are well known for such layers.

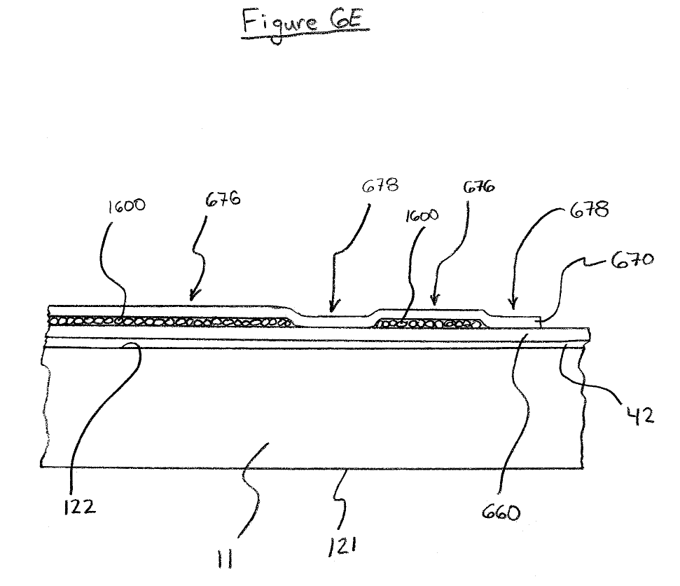

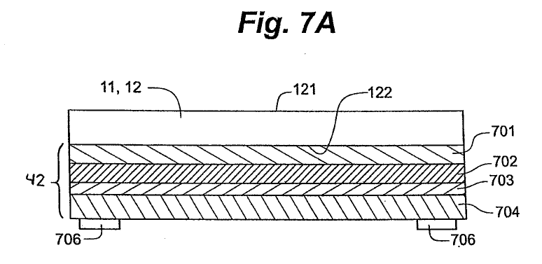

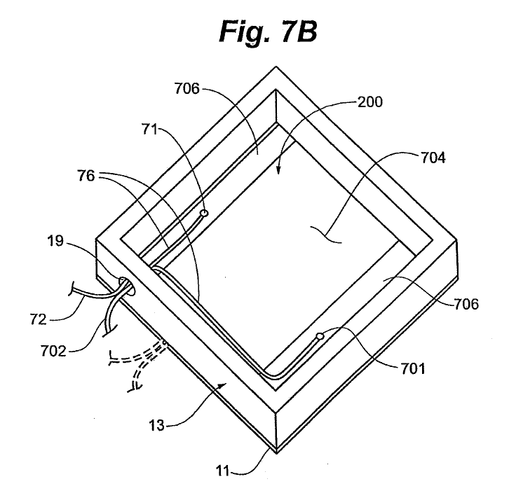

One embodiment of a photovoltaic coating is shown in FIG. 7A, which is a cross section of a substrate 11, 12 bearing the photovoltaic coating 42 directly on the second surface 122. In this case, the coating 42 is of the thin film variety and includes, from substrate 11, 12 outward, a first layer 701 formed of a transparent conductive oxide (TCO), for example, comprising tin oxide, a semiconductor layer 702, for example, comprising two “sub-layers”: cadmium sulfide (“window” layer; n-type), over layer 701, and cadmium telluride (absorbing layer; p-type), over the cadmium sulfide. FIG. 7A further illustrates an electrical contact layer 703, for example, comprising nickel, a contact layer 704, and a bus bar 706 to which electrical lead wires may be coupled for collecting electrical energy generated by the photovoltaic coating 42. It is to be appreciated that this is merely one example of a photovoltaic coating; any other photovoltaic coating can be used. Lead wires can be routed out from between the substrates 11, 12 by having them pass through openings 18 and/or seal opening 19 (FIG. 3), or through the seal system 13 (FIG. 7B).

In preferred embodiments, the efficiency of the photovoltaic coating is dependent upon the temperature of the coating. For example, the efficiency may decrease with increasing temperature. Thus, the coating will commonly be a temperature-sensitive photovoltaic coating. Some preferred embodiments of the assembly 10 are therefore designed to keep the temperature of the photovoltaic coating relatively low. Preferably, a narrow gas space 200 is included between the second surfaces of the first and second substrates. The gas space may be referred to as an airspace, gas space, gap, or interpane space. The air space can be filled with any type of gas, not just air. Preferably, the gas space is not under vacuum and comprises gas at a pressure of at least about 75 kPa, or at least about 100 kPa. In some embodiments, the gas in the gas space may have a slightly positive pressure.

The gas space preferably is sized to facilitate heat transfer from the photovoltaic coating to an environment external to the assembly. Thus, in certain embodiments, the assembly is configured to keep the photovoltaic coating relatively cool. To accomplish this goal, the assembly can optionally have a single (i.e., only one) interpane space, which preferably is extremely narrow. Providing a thick gas space and/or adding gas spaces to both sides of the photovoltaic coating would have a negative impact on the performance of the assembly (e.g., the temperature of the photovoltaic coating would be higher, and the overall efficiency of the assembly would therefore be worse).

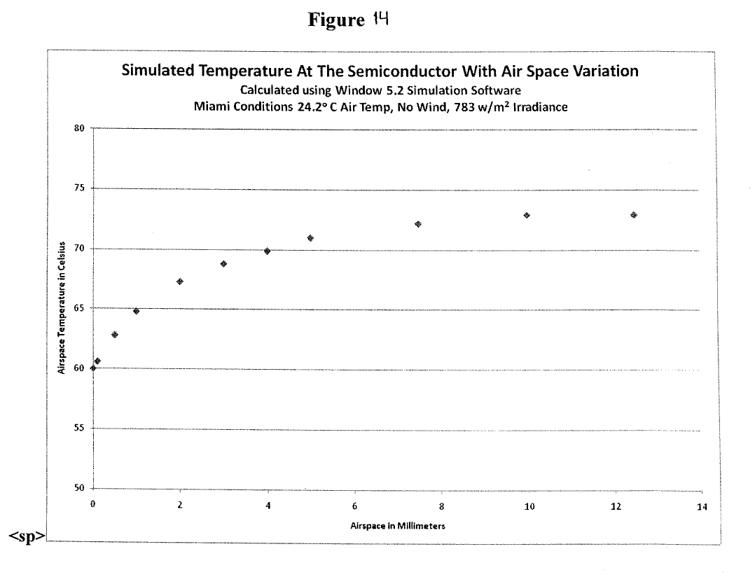

To study the effect different gas space thicknesses have on the temperature of a photovoltaic coating, a series of tests were performed in which different gas space thicknesses were used and the temperature of the photovoltaic coating was determined. Both physical and simulated tests were conducted to determine the relationship between gas space thickness and panel temperature. The data shown in FIG. 14 were developed. The data show that increasing the gas space thickness has a substantial effect on semiconductor temperature. Moreover, when the gas space thickness is less than approximately 0.1 inch (2.54 mm), the semiconductor temperature drops off rapidly. To take advantage of this, the gas space thickness in certain preferred embodiments of the assembly 10 is less than approximately 0.1 inch.

The results of the testing reported in FIG. 14 were confirmed by constructing twelve modules of varying gas space thickness, ranging from 1 to 4 mm, with thermocouples adhered to the surface where the semiconductor would traditionally sit. These modules were exposed outdoors in Minneapolis, Minn. and temperature recorded every 10 seconds over a period of 8 days. The results are summarized below.

Average Semiconductor Temperature By Airspace Thickness
Samples Mounted South Face At 45 Degrees,
Average of Temperatures At Irradiance Levels 750 w/m2 And Above
All Wind Levels

| 1 mm Airspace | 2 mm Airspace | 4 mm Airspace |
|---|---|---|
| 50.84° C. | 52.81° C. | 53.91° C. |

The results of this testing confirm the original simulation data.

At higher temperatures, the efficiency of a photovoltaic panel decreases. This is known as the Power Temperature Coefficient. A typical coefficient is approximately −0.25%/C. Meaning the panel will lose 0.25% efficiency for every degree Celsius increase in panel temperature. For the Minneapolis data above, this would indicate that in going from 1 to 4 mm, the power output of the panel would be around 0.77% lower. In the context of a photovoltaic device, an increase of this magnitude is a significant improvement. Based on these experiments, certain preferred embodiments of the assembly provide a single gas space having a thickness of less than 0.1 inch, such as 0.095 inch or less (e.g., between 0.01 inch and 0.095 inch), so as to facilitate heat transfer from the photovoltaic coating, hence keeping it relatively cool.

Thus, certain embodiments provide an extremely narrow gas space 200 across which heat can be transferred relatively freely. In such embodiments, the heat transfer preferably lowers the temperature of the photovoltaic coating. As discussed above, lowering the temperature of the photovoltaic coating will generally increase the efficiency of the coating. Increasing the efficiency, in turn, will generally lower the cost per unit output of power.

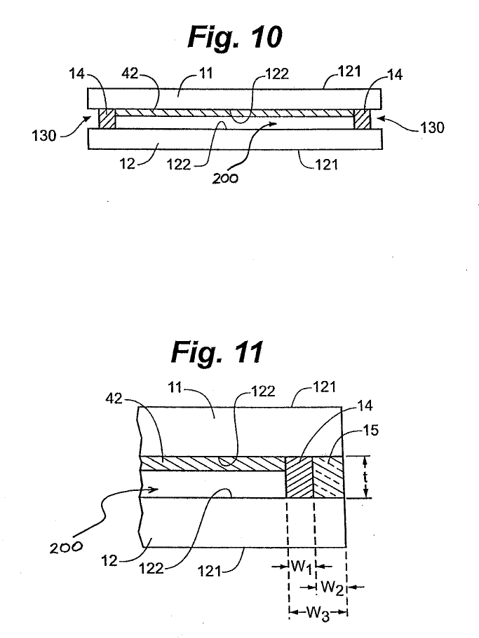

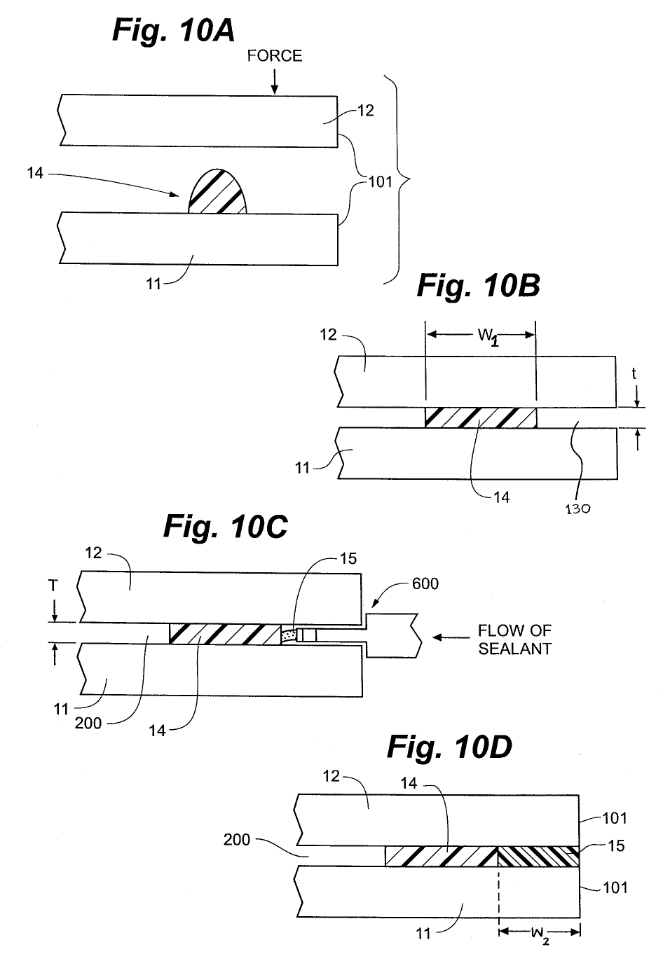

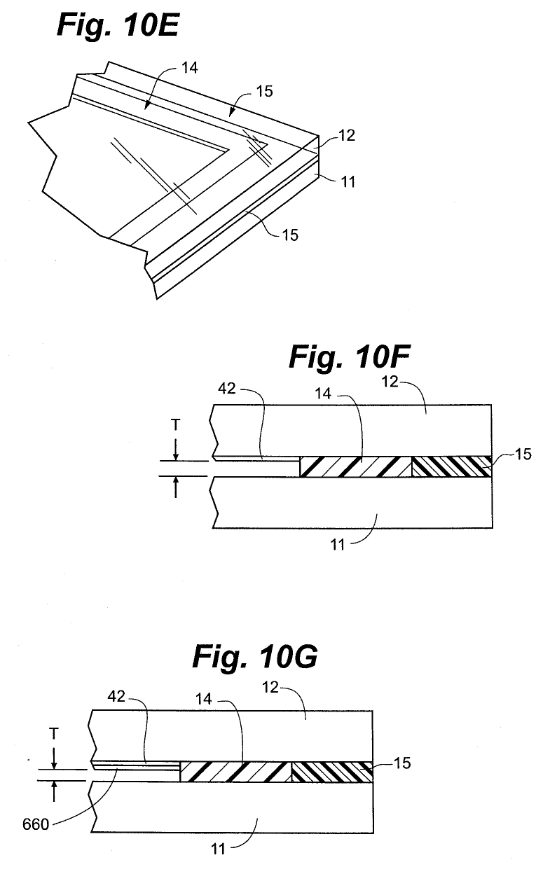

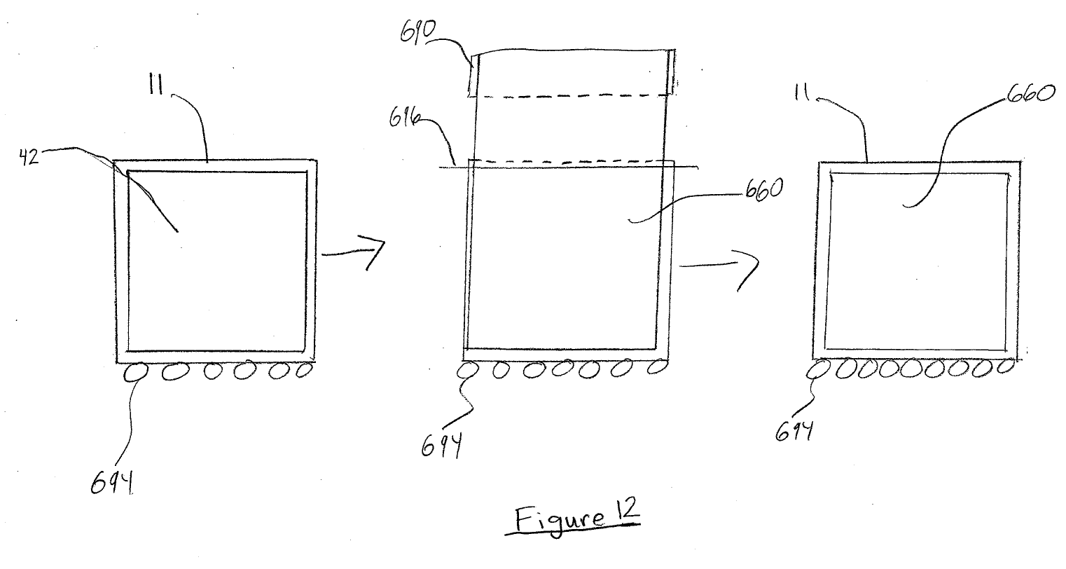

In one group of embodiments, the gas space 200 has a thickness T (reference is made to FIGS. 3, 10C, 10F and 10G) of between approximately 0.005 inch and approximately 0.2 inch, such as between approximately 0.01 inch and approximately 0.1 inch. In certain preferred embodiments, the thickness T is between 0.01 inch and 0.09 inch, such as between 0.01 inch and 0.085 inch, or between 0.01 inch and 0.08 inch. In some cases, the thickness T may range between 0.01 inch and 0.07 inch, such as between 0.01 inch and 0.06 inch.

Some embodiments provide the assembly 10 with a gas space thickness T that is extremely small relative to the area of the gas space. This relative dimensioning limits the edge seal area that is available for gas and moisture passage, while at the same time providing a gas space area A that can receive a large amount of desiccant. In some embodiments, with reference to FIG. 3, the area A of the gas space (which is measured parallel to the second surface of one or both substrates, e.g., as the product of a length and width of the gas space) is configured to provide a T/A radio of less than about 2.6×10⁻⁴/inch, or less than about 8.7×10⁻⁵/inch, such as less than about 5.5×10⁻⁵/inch. As just one example, if the gas space area A is about 24 inches by 48 inches (totaling 1152 square inches) and the thickness T is about 0.06 inch, then the T/A ratio is about 5.2×10⁻⁵/inch. In this example, the gas space preferably is provided with at least about 5 grams of desiccant (e.g., beaded desiccant), or perhaps more preferably at least about 50 grams of desiccant.

As noted above, the photovoltaic glazing assembly 10 preferably includes only one gas space 200. In embodiments of this nature, the assembly preferably has only two substrates (e.g., only two glass panes). Such embodiments are useful for maximizing heat transfer away from the photovoltaic coating. In contrast, a panel with three or more substrates (e.g., three or more glass panes) creating additional interpane spaces would increase the thermal insulation value of the panel, thus reducing heat transfer away from the photovoltaic coating.

In certain preferred embodiments, the assembly 10 is configured such that there is only one substrate (e.g., only one glass pane) between the source of radiation (e.g., the sun) and the photovoltaic coating. For example, the assembly 10 in certain embodiments is configured such that solar radiation first enters the assembly 10 through the substrate (e.g., through a glass pane) on which the photovoltaic coating 42 is provided. Reference is made to FIG. 3A.

FIG. 3 illustrates a gas space 200 located between the second surfaces 122 of the two substrates 11, 12. Referring to FIGS. 10C, 10F and 10G, it can be seen that the gas space may be bounded by the photovoltaic coating 42, the retention film 660, and/or interior substrate surface(s) 122. For example, the gas space 200 in some embodiments is defined between an exposed surface 45 (see FIG. 3A) of the retention film 660 and the second surface 122 of the opposed substrate.

Preferably, the photovoltaic glazing assembly 10 is devoid of any metal spacer (or any tubular spacer of another material), such that the peripheral seal system alone (which can optionally consist essentially of two polymer seals) physically separates the peripheries of the first and second substrates. Thus, the peripheral seal system between the two substrates can optionally consist essentially of contiguous first and second seals each comprising a polymer. In some embodiments of this nature (e.g., FIG. 10D), the seal system has the same thickness as the gas space. In other cases (e.g., FIGS. 10F and 10G), the thickness t of the seal system 13 sets (e.g., defines a maximum for) the gas space thickness T, but the gas space thickness T is slightly smaller than the seal system thickness t.

Thus, preferred embodiments of the photovoltaic glazing assembly 10 include a seal system 13 for sealing the gas space 200 from an external environment. Such seal systems are useful for greatly reducing the amount of gas that crosses the seal system into or out of the gas space. Certain gases, such as water vapor, can corrode the photovoltaic coating and reduce its efficiency. In some embodiments, the peripheral seal system includes (or consists essentially of) an inner seal (sometimes referred to as the first seal) 14 and an outer seal (sometimes referred to as the second seal) 15, each extending between the two substrates, so as to seal the first and second substrates to each other along their peripheries. In certain preferred embodiments, the inner 14 and outer 15 seals are contiguous to each other (optionally such that substantially no air pockets exist between them). Similarly, there are no air pockets (or substantially no air pockets) between the seal system 13 and the two substrates in preferred embodiments.

The present invention also includes advantageous manufacturing methods for the photovoltaic glazing assembly 10. Reference is made to FIGS. 10A-10D. In FIG. 10A, a bead of the inner seal 14 (optionally PIB) is applied to one of the substrates such that the bead is spaced from the adjacent edge 101. As shown in FIG. 10A, in some embodiments the first seal 14 has a generally half-round configuration when initially applied. This bead preferably extends entirely about the periphery of the substrate to which it is applied. (The photovoltaic coating and retention film are not shown in FIGS. 10A-10D, but both would preferably be applied to at least a central region of one of the substrates.) Force is applied as shown schematically in FIG. 10A. This compresses the bead of the inner seal 14 between the two substrates, and in the process, reduces the thickness t of the bead while simultaneously increasing its width W₁. In some embodiments, the final width W₁ of the inner seal 14 is at least 0.1 inch, at least 0.2 inch, or at least 0.25 inch, such as about 0.27-0.32 inch, while the final thickness t of the inner seal is less than 0.1 inch, less than 0.09 inch, or less than 0.085 inch, such as about 0.04-0.08 inch. The dimensions of the inner seal 14, however, can be varied to meet the requirements of different applications. Therefore, the noted dimensions are by no means required.

Once the inner seal has been compressed, a peripheral channel 130 is defined collectively by the inner seal and the interior peripheral surfaces of the substrates. The outer seal 15 is then applied into this channel. In FIG. 10C, the tip of a nozzle 600 is inserted into the peripheral channel, preferably such that the leading end of the nozzle's tip is adjacent to (e.g., nearly touches) the inner seal 14. The nozzle is operated so as to fill the channel with the outer sealant, preferably all the way around the periphery of the panel. In some cases, the tip of the nozzle is maintained in the noted position as the nozzle is moved entirely about the perimeter of the panel, all the while flowing sealant material (optionally silicone) into the channel. Once this is done, the channel preferably is substantially entirely filled with the outer sealant material, optionally such that the outer face of the outer seal is generally or substantially flush with the edges 101 of the substrates 11, 12. Using this method, the two seals 14, 15 can be applied with no air (or substantially no air) between them, and with no air (or substantially no air) between the substrates 11,12 and the seals. This is desirable because air pockets between such seals can cause a breach in the seal system (e.g., when the temperature of the assembly 10 increases, the air pocket can blow out through one of the seals 14, 15).

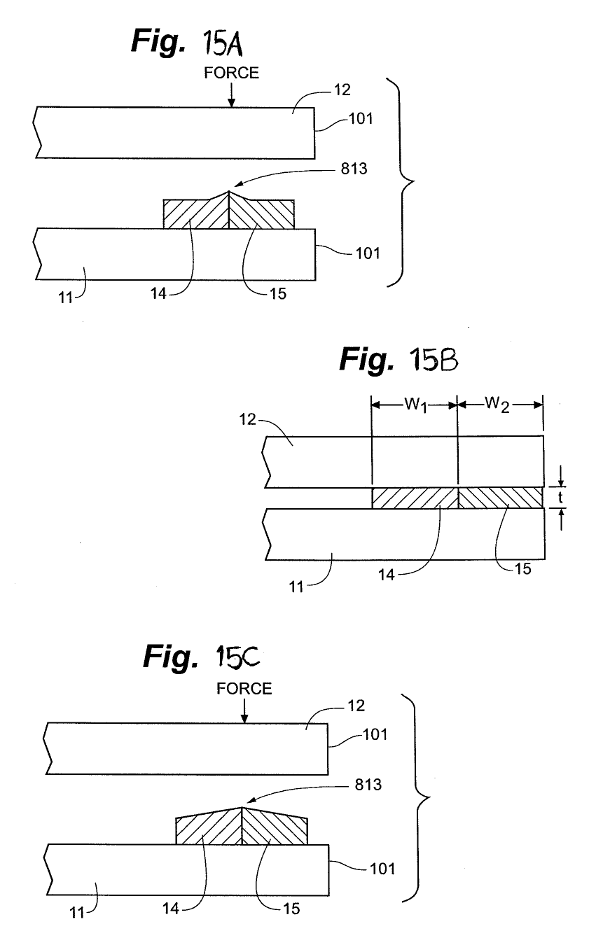

FIGS. 15A-15C exemplify another group of advantageous method embodiments. Here, the method involves providing first and second substrates, each having first and second major surfaces. The second surfaces each have a central region and a periphery. Preferably, at least one of the substrates is transparent, and a photovoltaic coating is on at least the central region of the second surface of the first or second substrate. The methods exemplified by FIGS. 15A-15C include applying a ribbon (or “bead”) comprising side-by-side first 14 and second 15 seals to the periphery of at least one of the second surfaces, such that when the ribbon is initially applied it has a thickness t that is greater adjacent to (e.g., at) a midpoint of the ribbon than adjacent to sides of the ribbon (optionally such that the ribbon when initially applied is spaced inwardly from the edge 101 of the underlying substrate 11). Thus, when the ribbon is initially applied, it has a configuration characterized by a raised central portion 813. This can be appreciated by referring to FIGS. 15A and 15C. Here, the midpoint of the illustrated ribbon is adjacent to an interface between the first 14 and second 15 seals. Thus, in certain preferred embodiments, the thickness t of the ribbon is greatest adjacent to (e.g., at) the midpoint of the ribbon, adjacent to (e.g., at) the interface between the two seals, or both. In preferred embodiments, when the ribbon is applied, the two seals 14, 15 are contiguous (i.e., touching each other) such that there are no air pockets (or substantially no air pockets) between the two seals.

In FIGS. 15A-15C, the configuration of the ribbon is such that when it is squeezed between the two substrates, the resulting deformation of the ribbon causes the sealant material of the ribbon to wet the second surface of the confronting substrate 12 without trapping air between that substrate and the ribbon. Thus, in certain preferred embodiments, the ribbon when initially applied has a tapered configuration, optionally such that a taper extends entirely (or at least substantially entirely) between each side of the ribbon and its midpoint (or another central point of the ribbon where its thickness is greatest). In embodiments of this nature, the thickness of the ribbon will generally be less adjacent to each side of the ribbon than adjacent to a midpoint or some other central point of the ribbon. In some embodiments of this nature, when the ribbon is initially applied, its exposed top face is defined by surfaces (optionally two slanted surfaces) that are at least generally (or at least substantially) planar, rather than having a convex configuration. This is best appreciated by referring to FIG. 15C. To apply a ribbon (or “bead”) of this nature, a nozzle can be used (e.g., a nozzle with an interior cavity shaped like the bead to be applied).

Thus, the present methods include bringing the first and second substrates together in an opposed relationship such that the ribbon is between the peripheries of the second surfaces of the substrates, and applying pressure (e.g., force, see FIGS. 15A and 15C) so as to move the first and second substrates closer together until the thickness t of the ribbon is at least substantially uniform from the midpoint to the sides of the ribbon (see FIG. 15B). Due to the ribbon configuration here, when force is applied to one or both substrates, the raised central portion 813 is deformed in a manner that tends to push air (which initially occupies space between the ribbon and the confronting substrate 12) outwardly beyond the sides of the ribbon, so as to eliminate (or at least substantially eliminate) air between the ribbon and the two substrates. FIG. 15B exemplifies embodiments wherein after the pressure application step, an exterior side of the ribbon is at least generally flush with the edges 101 of the first and second substrates, although this may not be required. In some embodiments, at least one of the substrates is a glass sheet, the first seal comprises a butyl sealant material, and the second seal comprises a material selected from the group consisting of silicone, polysulfide, and polyurethane.

Methods like those exemplified in FIGS. 15A-15C may be particularly advantageous for embodiments wherein the thickness t of the seal system is particularly small, e.g., less than 0.08 inch, less than 0.07 inch, less than 0.06 inch, or even less than 0.05 inch. It is to be appreciated, however, that the present methods are by no means limited to use with any particular seal system thickness. Rather, this will vary with different applications.

According to some embodiments, the first seal 14 may comprise (or consist essentially of) an extrudable material such as a polymeric material, which preferably is largely impermeable to moisture vapor and gases (e.g., air or any gas fill). In some preferred embodiments, the first seal 14 has a moisture vapor transmission rate (MVTR) there through that does not exceed approximately 10 g mm/m²/day when measured according to ASTM F 1249 at 38° C. and 100% relative humidity. In some preferred embodiments, the first seal has a MVTR that does not exceed approximately 5 g mm/m²/day, and more preferably does not exceed approximately 1 g mm/m²/day.

In some embodiments, the first seal 14 has good adhesion properties, so as to be useful for bonding the first and second substrates together. Examples of suitable materials include both non-setting materials and setting materials, e.g., cross-linking materials, and may include thermoplastic materials, thermosetting materials, or air, moisture or UV curable materials. Materials suitable for use as the first seal 14 preferably having low conductivity or electro conductivity. An international test standard for low conductivity is the IEC 61646 International Standard for Thin-Film Terrestrial Photovoltaic (PV) Modules—Design Qualification and Type Approval (“IEC 61646 Standard”). Materials particularly suited for use in embodiments of the invention are those that meet the IEC 61646 Standard. In some preferred embodiments, the first seal 14 comprises a butyl sealant, such as polyisobutylene (PIB) or butyl rubber.

In some embodiments, the first seal 14 is “desiccant free,” meaning it does not have desiccant embedded or mixed into the sealant material. Non-limiting, commercially available examples of materials that can be used for the first seal 14 (which exhibit one or more of the above-noted desirable properties, e.g., low MVTR and low conductivity) include but are not limited to Adcotherm™ sealants such as PIB 7-HS, PIB 8-HS and PIB 29 available from ADCO Products Inc., of Michigan Center, Mich., U.S.A. In some alternate embodiments, the first seal 14 includes a desiccant, e.g., embedded or mixed into the sealant material. For example, the first seal 14 may comprise a thermoplastic material into which a drying agent is mixed. An example of a seal including desiccant is disclosed in U.S. Pat. No. 6,673,997. Commercially available materials that may be used include, for example, HelioSeal™ PVS-110 and Kodimelt TPS, both available from ADCO Products, Inc.

Certain embodiments include an inner seal 14 with a large width W₁ relative to its thickness t. Such an inner seal provides a long path along which gas must travel to enter or exit the gas space, while at the same time providing a relatively small area against which the gas can act. As shown in FIG. 10B, in some embodiments the inner seal 14 has a width W₁ (e.g., measured parallel to the second surfaces) and thickness t that provide a W₁/t ratio of at least 2, at least 2.5, at least 3, or at least 4, such as about 4.2-7.5. In one embodiment, the inner seal 14 has a thickness t of about 0.04 inch to about 0.08 inch, while the width W₁ is about 0.27 inch to about 0.32 inch, such that the W₁/t ratio is about 3.3 to about 8.0. Again, the noted dimensions and ratios can be varied to meet the requirements of different applications.

In preferred embodiments, the seal system 13 also includes a second or “outer” seal 15, which preferably is positioned against the inner seal. Such a seal can provide an additional barrier against gas migrating into or out of the gas space and/or it can provide adhesion between the substrates 11, 12. In certain preferred embodiments, the second seal 15 comprises (or consists essentially) of a material selected from the group consisting of silicone, polysulfide, and polyurethane.

In some embodiments, the second seal comprises a composition including one or more silyl containing polyacrylate polymers. The second seal may comprise a silyl terminated polyacrylate polymer. In some embodiments, the silyl terminated polyacrylate polymer has an average of at least 1.2 alkoxysilyl chain terminations per molecule. For example, the silyl termination portion of the silyl terminated polyacrylate polymer may be described by the following average formula:

—SiR¹ₓ(OR)₃₋ₓ

where R is methyl, ethyl, n-propyl, or isopropyl, R1 is methyl or ethyl, and x is 0 or 1.

The composition may further comprise a catalyst. In some embodiments, the catalyst is a metal catalyst such as a tin or a titanium catalyst. In some embodiments, the catalyst is a carboxylic acid metal salt. Examples of carboxylic acid metal salts which may be used include calcium carboxylate, vanadium carboxylate, iron carboxylate, titanium carboxylate, potassium carboxylate, barium carboxylate, manganese carboxylate, nickel carboxylate, cobalt carboxylate and zirconium carboxylate. Examples of useful carboxylic acids are disclosed in U.S. Pat. No. 7,115,695 to Okamoto et al., the relevant portions of which are hereby incorporated by reference.

In various embodiments, another example of silyl containing polyacrylate polymer useful as the second seal is formed of a silyl terminated acrylic polymer such as XMAP™ polymer, available from Kaneka Corporation (Osaka, Japan). The second seal may be formed from XMAP™ polymer alone or in combination with one or more other polymers.

In addition, the composition of the second seal may comprise fillers, such as calcium carbonate, silica, clays, or other fillers known in the art. The second seal may also include a variety of other additives including, but not limited to, crosslinkers, plasticizers, thixotropic agents, UV absorbers, light stabilizers, dehydration agents, adhesion promoters, catalysts, titanium dioxide, ground and/or precipitated calcium carbonate, talc and other suitable additives.

The silyl terminated polyacrylate polymers, such as XMAP™ polymers, may be used in the second seal to provide a strong and weather resistant adhesive. Unlike conventional silicone sealants, XMAP™ polymer lacks volatile cyclic silicone compounds and releases only very low levels of volatile non-cyclic silicone compounds. This may be advantageous.

The XMAP™ polymer is represented by the formula:

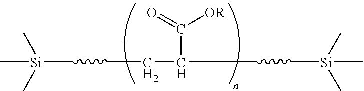

R may be a hydrocarbon group with one free bond for attachment or a hydrocarbon group with one available bonding site. In some embodiments, R is a butyl or an ethyl group. Non-limiting examples of R functional groups include but are not limited to methyl, ethyl, n-propyl, isopropyl, n-butyl, isobutyl, tert-butyl, n-pentyl, n-hexyl, cyclohexyl, n-heptyl, n-octyl, 2-ethylhexyl, nonyl, decyl, dodecyl, phenyl, tolyl, benzyl, 2-methoxyethyl, 3-methoxybutyl, 2-hydroxylethyl, 2-hydroxylpropyl, stearyl, glycidyl, 2-aminoethyl, gamma-(methacryloyloxypropyl)trimethoxysilane, ethylene oxide adduct of (meth)acrylic acid, trifluoromethylmethyl, 2-trifluoromethylethyl, 2-perfluoroethylethyl, 2-perfluoroethyl-2-perfluorobutylethyl, 2-perfluoroethyl, trifluoromethyl, bis(trifluoromethly)methyl, 2-trifluoromethyl-2-perfluoroethylethyl, 2-perfluorohexylethyl, 2-perfluorodecylethyl and 2-perfluorohexadecylethyl. Examples of monomers which may be used in the invention are described in U.S. Patent Publication Number 2006/0252903, the relevant portions of which are hereby incorporated by reference. The molecular weight may be between approximately 500 and 100,000, and n may be between approximately 3 and approximately 100,000. For some embodiments, n may preferably be 50 or more; and in other embodiments n maybe 100 or more. For some other embodiments, n is preferably at least 200, and more preferably at least 400. XMAP™ polymers, when used in the second seal, may have low polydispersity (PDI) ranging from about 1.1 to about 1.6. They can be prepared with a molecular weight variety and have high end-functionality. A variety of polymer backbones may be used, i.e., a variety of homopolymers and copolymers of various acrylates. The polymer backbones typically have only carbon-carbon single bonds. The polymer also has carbon-silicon bonds at the telechelic ends and ester groups throughout the backbone. XMAP™ polymers can be liquid at room temperature. XMAP™ polymers can have a weathering resistance that is comparable to silicone sealants and may be resistant to heat at temperatures up to 300° F. In addition, they can be oil resistant. XMAP™ polymers can cure through various routes, including condensation, addition, or radical curing processes. They may be produced using living radical polymerization technology, as shown below:

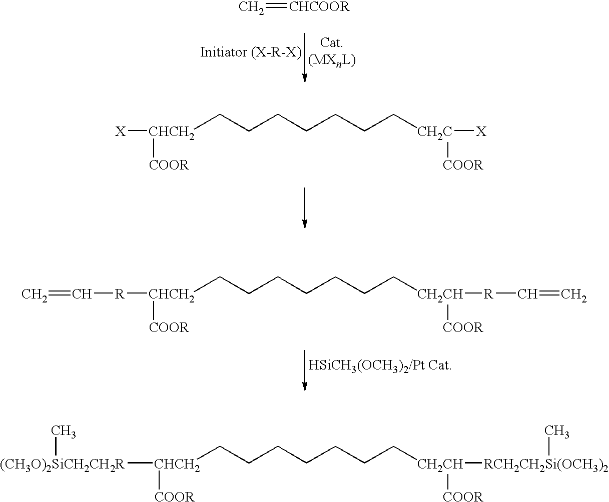

Certain embodiments provide a second seal 15 having a large width W₂ relative to its thickness t (the thickness t of the second seal will typically be at least substantially equal to the thickness t of the first seal). Such a seal provides a relatively long path along which gas must travel to enter or exit the gas space, while at the same time providing a relatively small area against which the gas can act. In some embodiments, as shown in FIG. 10D, the outer seal 15 has a width W₂ (e.g., measured parallel to the second surfaces) that provides a W₂/t ratio of at least 2, at least 2.5, at least 3, or at least 4. In one embodiment, the second seal 15 has a thickness t of about 0.04-0.08 inch, while the width W₂ is about 0.17-0.23 inch, such that the W₂/t ratio is about 2.1-5.8. Here again, the noted dimensions and ratios can be varied to suit different applications.

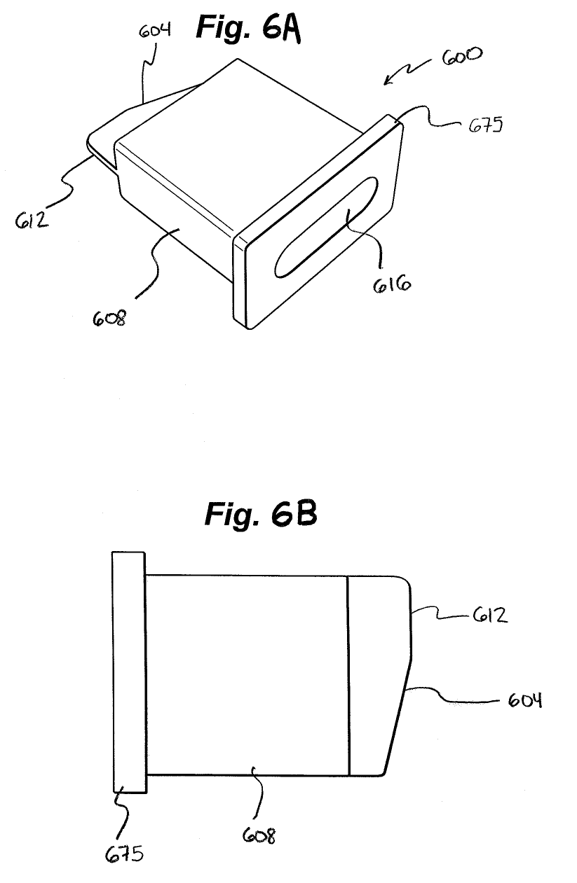

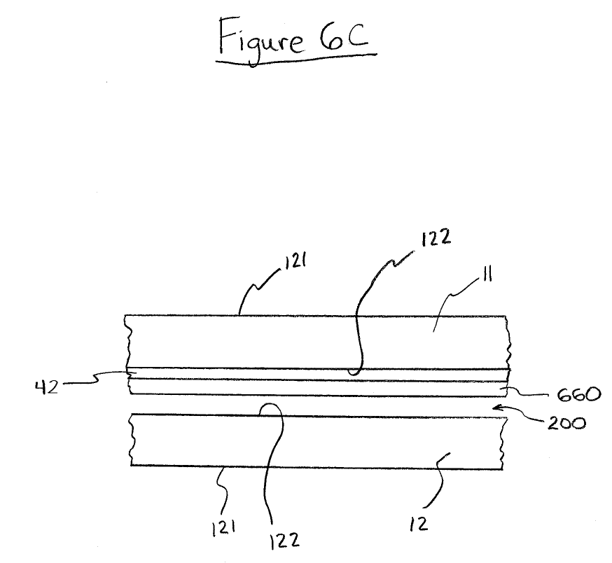

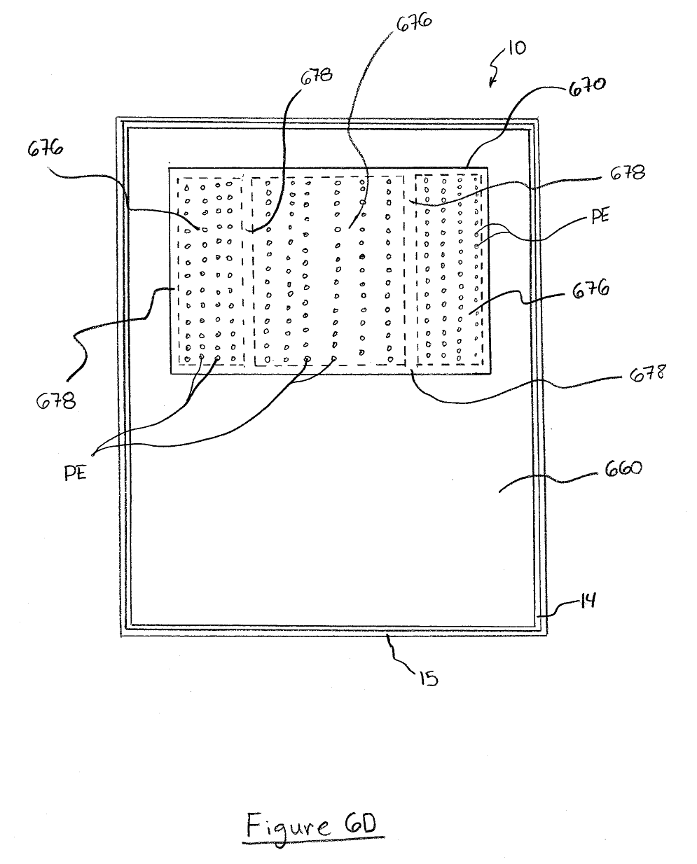

In some embodiments, the outer seal 15 is applied to the photovoltaic assembly using a nozzle 600 adapted to significantly reduce or eliminate air space between the two seals. As shown in FIGS. 6A, 6B and 10C, the nozzle 600 can have an outlet 604 adapted to deliver sealant material (optionally silicone) to a peripheral channel defined collectively by the inner seal and the second surfaces of the two substrates. In some embodiments, the outlet 604 is orientated at a skewed angle when the nozzle is operatively positioned to deliver sealing material into the channel. Such an angled outlet facilitates eliminating, substantially eliminating, or greatly reducing the amount of air that may be left between the inner and outer seals. In some embodiments, the nozzle 600 includes a relatively thick portion (or “base”) 608 and a relatively thin portion (or “tip”) 612, with the outlet 604 being on (e.g., defined by) the thin portion, and an inlet 616 defined by the thick portion. Preferably, as the nozzle is moved around the peripheral channel, the angled portion of the nozzle's tip (over part of which the opening extends) is on the trailing side, such that the bead of sealant being laid down trails much of the nozzle. Both nozzle portions 608, 612 collectively define a flow path for conveying sealant from the nozzle inlet to the outlet. Thus, the inlet 616 is in fluid communication with the outlet 604. In some embodiments, a flange 620 for attaching the nozzle to a pressurized and/or heated sealant supply projects from the thick portion. Thus, silicone or another sealant can be pushed (e.g., flowed) into the inlet, through the nozzle, and out of the outlet to fill the channel 130, preferably so as to position the second seal against (e.g., directly alongside) the first seal.

Referring to FIG. 11, the first seal 14 and the second seal 15 are shown having respective widths W₁ and W₂, while the seal system 13 has an overall width W₃, which represents the combined width of W₁ and W₂. In certain embodiments, the overall width W₃ of the seal system 13 is at least 0.2 inch, at least 0.3 inch, or at least 0.4 inch. In certain embodiments, the width W₃ is between about 0.2 inch and about 1.5 inches, or between about 0.3 inch and about 1.0 inch, such as about 0.34 inch-0.65 inch. Preferably, the thickness t of the seal system 13 is relatively small, as is perhaps best appreciated with reference to FIGS. 10A-10G. For example, the thickness t may be less than 0.1 inch, less than 0.09 inch, or less than 0.085 inch. In some embodiments, the overall width W₃ and the thickness t of the seal system 13 are selected to provide a ratio of W₃/t that is greater than 4, greater than 6, greater than 9, or even greater than 11. In one embodiment, the seal system 13 has a width W₃ of about 0.5-0.6 inch, while the thickness is about 0.04-0.08 inch, such that the W₃/t ratio is about 6.25-15. As noted above, dimensions of this nature can provide a long, narrow path along which gas must travel to enter or exit the gas space. It is to be understood, however, that the noted dimensions are merely examples: they are by no means limiting.

As noted above, a photovoltaic coating 42 is provided over at least the central region of the second surface 122 of one of the substrates 11/12. According to some preferred embodiments, the second major surface 122 of the first substrate 11 bears the photovoltaic coating 42. The coverage of the coating on the second surface 122 of the substrate 11/12 (relative to the location of the seal system 13) can vary according to different embodiments. Two examples are shown in FIGS. 4 and 5.

FIGS. 4 and 5 are section views through line A-A of FIG. 1, according to different embodiments. FIG. 4 illustrates a photovoltaic coating 42 over (e.g., directly on) only a central portion 103 (FIG. 2) of the second surface 122 of the first substrate 11, while the seal system 13 is only over a periphery 105 (FIG. 2) of the second surface 122. Here, the seal system 13 is not applied over the photovoltaic coating 42. FIG. 5 illustrates an alternate embodiment wherein the seal system 13 is applied over the periphery 105 and over an edge portion 420 of the photovoltaic coating 42. Other variants of this nature are possible.

In certain preferred embodiments, the photovoltaic glazing assembly is devoid of any laminated substrates, e.g., laminated glass panels. This lowers the cost of the photovoltaic glazing assembly substantially, thus increasing the likelihood of widespread adoption and use. The energy required to assemble the present photovoltaic assembly 10 is estimated to be about 1/7^{th} of the energy required to laminate a laminated glass panel. Many laminated glass panels are heat treated in an autoclave, which is a batch process requiring about 15 minutes per batch. In contrast, the present assembly 10 can be produced using a continuous, automated process wherein a completed unit takes about 30 seconds to assemble.

As shown in FIGS. 6C, 6D, 6E and 10G, certain preferred embodiments of the photovoltaic glazing assembly 10 include a retention film 660 over (optionally directly over) the photovoltaic coating 42, such that the photovoltaic coating is sandwiched between the retention film and the underlying substrate. In some embodiments, the retention film has an extremely small thickness and yet is able to (e.g., has a tear resistance and a flexibility sufficient to) hold the photovoltaic coating and the substrate together in the event of breakage. The retention film, for example, is able to pass the fracture test of the International Electrical Commission Standard 61730-2, section 10.10. Specifically, when the present assembly 10 is fractured by swinging a punching bag filled with 100 pounds of lead shot from a height of 48 inches, the retention film 660 prevents shards of glass larger than 1 square inch from breaking off the retention film. This high level of retention is achieved even though the retention film is not part of a laminated glass panel (in which bonding among two panes and an encapsulate provides reinforcement), but rather has a gas space between the two substrates. Such a retention film is particularly useful for retaining photovoltaic coatings containing materials that may generally be considered toxic.

The retention film 660 preferably comprises a flexible and electrically non-conductive film, which is optionally applied over approximately an entirety of the photovoltaic coating 42, such that the photovoltaic coating is sandwiched between the retention film and the underlying substrate. The retention film can be applied directly to the photovoltaic coating, or it can be applied over one or more intermediate films. The retention film itself can comprise or consist essentially of any suitable material (e.g., a polymer), such as a material selected from the group consisting of polyethylene, polypropylene, polyester, PVC, and combinations including one or more of these materials. In certain embodiments, the retention film 660 is carried directly against (e.g., is adhered directly to) the photovoltaic coating 42, in which case the retention film preferably does not contain EVA or PVB. More will be said of this later. The retention film can be generally transparent or opaque (e.g., black).

The retention film preferably has a thickness of less than 0.015 inch, less than 0.01 inch, less than 0.009 inch, or even less than 0.006 inch. In some embodiments, the thickness of the retention film 660 is between approximately 0.001 inch and approximately 0.015 inch, such as between 0.001 inch and 0.01 inch, or between 0.001 inch and 0.009 inch, or between 0.001 inch and 0.008 inch, such as between 0.001 inch and 0.007 inch. In certain embodiments, the thickness of the retention film is between 0.001 inch and 0.006 inch, such as between 0.001 inch and 0.005 inch. In one example, the thickness of the retention film is about 0.0035 inch. Thus, the retention film 660 provides good retention of glass and coating (e.g., it passes the above-referenced fracture test) even when it has an extremely small thickness and is used in a non-laminated assembly.

In some preferred embodiments, the photovoltaic glazing assembly is devoid of any ethylene vinyl acetate (EVA) in contact with the photovoltaic coating. It is desirable to eliminate contact between EVA and the photovoltaic coating because: 1) EVA can place a relatively high amount of water in contact with the coating, and 2) EVA may create acetic acid when it cross links. Water and acetic acid can both cause the photovoltaic coating to corrode. EVA can have a relatively high water content, e.g., a maximum solubility of roughly 1%, which in ppm is 1,000 ppm. By comparison, the gas space of the present assembly can have a much lower water content, e.g., on the order of 10 to 35 ppm. Thus, contact between EVA and the photovoltaic coating preferably is avoided in the present assembly. For similar reasons, contact between PVB and the photovoltaic coating preferably is avoided as well.

In some embodiments, the retention film has adhesive on one of its surfaces for adhering it to the photovoltaic coating, directly or via any intermediate layers. In certain embodiments, the adhesive has a sufficiently high bonding strength to maintain its adherence to the photovoltaic coating even if the substrate is broken. In certain preferred embodiments, the adhesive is a pressure-sensitive adhesive, such as an acrylic or rubber-based adhesive. In some embodiments, the retention film is a pre-formed film (although this, of course, is by no means required).

A dashed line in each of FIGS. 4 and 5 schematically represents an optional desiccant material enclosed within the gas space 200 to absorb moisture that may pass through the seal system 13 or otherwise be present in the gas space. Desiccant material can be provided in a variety of forms, including but not limited to wafer form, sheet or strip form, granular form, packaged in a sack or bag, “free-floating” in the gas space 200, adhered to one of substrates 11, 12, or otherwise present in the gas space 200. In other embodiments, the desiccant can be incorporated into the seal system 13 in the form of a commercially available desiccant-containing polymeric matrix material. Preferred desiccant materials are of the type commonly referred to by those skilled in the art as molecular sieves.

Desiccant wafers are commercially available from, for example, Sud-Chemie of Bellen, N. Mex., U.S.A. Desiccant in granular form is commercially available from, for example, Zeochem, Louisville, Ky., U.S.A.

Desiccant sheets and strips can be readily prepared by providing an adhesive sheet and applying desiccant in granular (or “beaded”) form to the adhesive. The adhesive may cover the entire surface of the sheet, or only certain regions (e.g., one or more central regions). When preparing such desiccant sheets, granules (or “beads”) will typically be adhered only to one or more central regions of the sheet, such that at least a periphery of the sheet is left with exposed adhesive (e.g., pressure-sensitive adhesive) that can be used to secure the sheet to the retention film (or to the substrate opposite that bearing the retention film). Suitable materials for the sheet include those that allow moisture to pass through or into them in order to be absorbed by the desiccant. The sheet material, for example, can be a polymer sheet having perforations PE through which moisture can pass. Reference is made to FIG. 6D. Here, desiccant is applied in a pattern onto, or only onto certain areas of, a sheet or film 670 having an adhesive on one side. The pattern can include alternating areas of desiccant material 676 bounded by areas devoid of desiccant material 678. Preferably, the desiccant material (e.g., granules or “beads”) are not applied to a periphery of the sheet or film 670, e.g., such that the entire periphery of the sheet or film can be adhered to the retention film (or another interior surface of the assembly), thereby trapping the desiccant material 1600 and holding it in place. This is perhaps best appreciated by referring to FIG. 6E. Such embodiments are useful for attaching the sheet or film 670 to the retention film 660 without needing additional fastening means.

Desiccant containing bags can be readily prepared, or can be commercially obtained from, for example, Sud-Chemie. Examples of commercially available desiccated polymeric matrix materials include but are not limited to the WA 4200, HA 4300, H9488J desiccated matrices from Bostik of Wauwatose, Wis., U.S.A., and the HL5157 desiccated matrix from HB Fuller Company of St. Paul, Minn., U.S.A.

According to some embodiments, the desiccant material (which preferably is in communication with the gas space 200) in combination with the seal system configuration (e.g., the large width to thickness ratio) and the low MVTR of the first seal 14 effectively prevent moisture build-up within the gas space 200 (which may otherwise lead to corrosion of certain elements of the photovoltaic coating or electrical connections or contacts). Preferred embodiments provide the gas space with a water content of less than 100 ppm, less than 50 ppm, or less than 45 ppm, such as about 10 to 35 ppm. The present assembly 10 can maintain a gas space water content within all of these ranges even after 9,000 hours of accelerated testing in accordance with the International Electrical Commission Standard 61646, section 10.13, Damp Heat Conditions of 85° C. and 85% RH.

The photovoltaic glazing assembly can optionally include one or more openings 18 formed in one or both substrates 11, 12, e.g., in the second substrate 12 as shown in FIG. 3, which shows a pair of optional openings 18. Openings 18, when provided, may be used to equalize pressure within the assembly 10 during manufacture or processing and/or to fill the gas space 200 with another gas, and/or to dispense a desiccant material into the gas space 200. Further, a pre-formed seal opening 19, as shown in FIG. 3, may be provided in addition to or instead of openings 18. When provided, such a seal opening 19 can be used for similar purposes.

FIG. 7B is a perspective view of a portion of a photovoltaic assembly similar to the assembly 10 of FIG. 1, wherein lead wires 76 extend through a seal opening 19 in the seal system 13 or between the seal system 13 and the second surface 122 of the first substrate 11.

FIG. 7B shows each lead wire 76 as having an inner terminal end 71, 701 coupled to a bus bar 706 of the photovoltaic coating 700 and located within the gas space 200, and each of the lead wires 76 is shown to have an outer terminal end 72, 702 located, outside the gas space 200. According to the illustrated embodiment, each inner terminal end 71, 701 can be coupled to a bus bar 706 of the coating 700 prior to affixing the first and second substrates 11, 12 together with the seal system 13, and then the outer terminal ends 72, 702 can be coupled to a power transmission system, power collection or storage system, or a load upon installation of the completed photovoltaic assembly. Thus, opening(s) 18 (FIG. 3) are not required for embodiments wherein wire routing like that in FIG. 7B is used, nor for other wire routing embodiments the lead wires are passed out from the gas space 200 between the seal system 13 and the first substrate 11, e.g., as illustrated with dashed lines in FIG. 7B. While opening 18 may not be required when a seal opening 19 is provided (or when the wiring is routed between a second surface 122 and the seal system 13), both can be provided in some embodiments. Whether used alone or in conjunction with at least one opening 18, a seal opening 19 can serve substantially the same purpose as opening 18, e.g., pressure equalization, filling the gas space 200 with a gas, dispensing or depositing a desiccant material into the gas space 200, and/or providing access for manufacturing operations performed within the gas space 200.

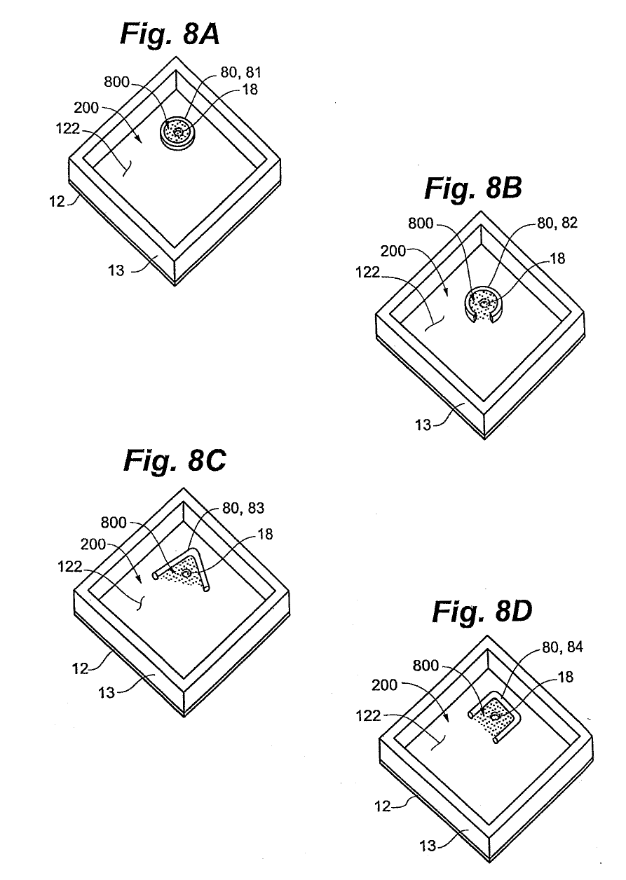

With reference to FIGS. 8A-D, the assembly 10 according to some embodiments includes a seal member 80 that surrounds, partially surrounds, or borders an opening 18 in one of the substrates 11, 12. In FIGS. 8A-D, exemplary seal members 80 are illustrated. These seal members 80, when provided, provide a partial back stop against or enclosure into which potting material can be applied and deposited to seal the opening 18. In certain embodiments, the potting material comprises a silyl containing polyacrylate polymer, e.g. a silyl terminated acrylic polymer such as a XMAP™ polymer, either alone or in combination with one or more other polymers. The illustrated seal member 80 contains a deposit of potting material 800 that is located over and/or around the opening 18. The seal member 80, when provided, may be useful for keeping a potting material that cures or sets in place while curing or setting. The seal member may be extruded, preformed, or otherwise applied, e.g., as a deposit of a polymeric or other suitable material. In some embodiments where the seal member 80 is applied or deposited around the perimeter of an opening 18, any of the extrudable materials suitable for use as the first seal 14 may be used to form the seal member 80. For example, the seal member 80 can comprise PIB. When provided, the seal member 80 can optionally be sandwiched between the retention film 660 and the second substrate 12. In some embodiments, when the two substrates 11, 12 are pressed together the seal member 80 is compressed, e.g., in the process, decreasing its thickness while simultaneously increasing its width.

FIG. 8A shows the assembly 10 having a circular shaped seal member 81 having a thickness that spans the gas space 200. FIG. 8A shows the seal member 81 completely surrounding the perimeter of the opening 18. FIG. 8B shows a C-shaped seal member 82, which also has a thickness that spans the gas space 200, but which only partially surrounds the periphery of the opening 18. FIG. 8C shows a V-shaped seal member 83, also having a thickness that spans the gas space 200, but which only partially surrounds the periphery of the opening 18. FIG. 8D shows a generally rectilinearly shaped seal member 84, partially surrounding the periphery of the opening 18 and having a thickness that spans the gas space 200. In some embodiments, a seal member of this nature has a thickness that is less than (e.g., slightly less than) that of the seal system 13.

According to the illustrated embodiments, after the opening 18 has provided any necessary access to the gas space, a potting material 800 is applied to seal the opening 18, and the seal member 80 provides a barrier or backstop to control any flow of potting material 800. As previously described, the opening 18 may further provide a passageway for routing lead wires from the photovoltaic coating (or a bus bar in contact with the photovoltaic coating); in such embodiments, the potting material 800 is applied around the lead wires within opening 18.

The present assembly 10 can optionally include one or more support members. Support members, when provided in the gas space, can provide additional support and stability to the spaced substrates 11, 12. Additionally, such support members can help prevent any narrowing or collapse of the gas space. This may be desirable, for example, when assemblies are manufactured at high altitude and transported through or installed in lower altitude areas. Support members may also increase the heat transfer across the gas space, thereby decreasing the temperature of the assembly 10. A variety of materials can be used as support members. Suitable materials may be flexible or resilient, and preferably have a durometer sufficient to withstand the normal thermal expansions and contractions of the assembly 10. The support members may be extruded elements, preformed elements, or elements applied as a deposit of a polymeric or other suitable material. In certain embodiments, support members formed of a polymeric material are provided. In many cases, though, it will be unnecessary to provide such support members between the panes. Thus, some embodiments provide a gas space 200 that is devoid of pillars or other support members located inwardly of the seal system 13. In other embodiments, there may be one or more seal members 80 surrounding respective openings 18, but otherwise the gas space 200 is devoid of pillars or any other support members located inwardly of the seal system 13.

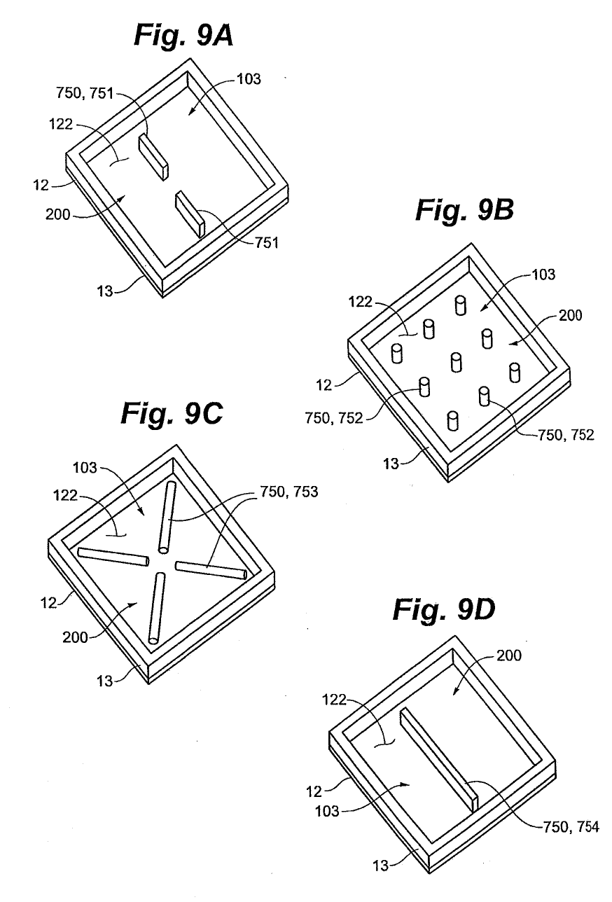

FIGS. 9A-D are perspective views of a portion of a photovoltaic assembly, for example, similar to assembly 10, shown in FIG. 1, wherein the first substrate 11 is removed for clarity in illustration. The support members 750 shown in FIGS. 9A-D are illustrative, non-limiting examples. As can be seen, the support members 750, when provided, can take a variety of shapes and configurations.

FIG. 9A illustrates two support members 751 each having a thickness that spans the gas space 200. Each support member 751 is shown extending over a portion of central region 103. FIG. 9B illustrates an array of support members 752 each having a thickness that spans the gas space 200. Here, the support members are pillars. FIG. 9C illustrates another plurality of support members 753 each having a thickness that spans the gas space 200. The support members here extend generally diagonally between opposing corners of the illustrated gas space 200. FIG. 9D shows a single support member 754 having a thickness that spans the gas space 200. This support member 754 is an elongated bar located over a portion of central region 103. Support members 750, 751, 752, 753, 754 can be formed from the same materials mentioned above in connection with the seal members 80, 81, 82, 83, 84.

In some embodiments, an extrudable material suitable for use as the first seal 14 can also be deposited as a support member 750. While the support members 750 in any of their various configurations can have a thickness that spans the gas space 200, the support members can alternatively have a smaller thickness and need not span the gas space 200. When provided, the support members preferably do not completely divide the gas space 200 into multiple compartments; however, if support members are so applied, desiccant may be provided in each compartment, or means for fluid communication may be provided between such compartments. Also, an opening 18 or seal opening 19 may be associated with each such compartment.

When provided, the support members can be formed, for example, of discrete polymeric deposits, and/or by extrusion of the same material that is used for the first seal 14. In some cases, the support members are applied as pre-formed bumpers, such as self-adhering bumpers (e.g., commercially available 3M Bumpon™ bumpers). In some embodiments, the support members have a desiccant incorporated into them. Some polymeric materials, of course, may require application of heat to secure and affix them in place.

The invention also provides methods for making photovoltaic glazing assemblies, including any of the assemblies described above. In some embodiments, the method includes providing first and second substrates, optionally glass substrates. The method can optionally include forming a photovoltaic coating on at least the central region of the second surface of one of the substrates. Alternatively, the method can simply involve providing a substrate that already has the photovoltaic coating in place. Preferably, the method includes applying a first seal to the periphery of at least one of the substrates, e.g., such that the first seal is spaced inwardly from the edges of the substrate, as described above in connection with FIGS. 10A-10C. The method involves bringing the first and second substrates together in an opposed relationship, preferably such that the first seal is aligned between the peripheries of the two substrates, and applying pressure to the assembly so as to join the two substrates together. Reference is made to the discussion above regarding FIGS. 10A and 10B. The two substrates are pressed together until the desired gas space thickness T is reached, at which point the two substrates may be held for a period of time (e.g., several seconds) to allow the first seal to complete its deformation. In embodiments involving two seals, the method includes applying a second seal into the peripheral channel 130. This can be done by holding the assembly 10 in a stationary position and moving a nozzle 600 (like that shown and described above) entirely around the perimeter of the assembly, so as to fill the channel 130 in the manner described above with reference to FIG. 10C. The second seal can thus adhere to the first seal without 24 air spaces (or at least without substantial air spaces) being formed between the seals.

Some methods for making the photovoltaic assembly 10 include one or more initial method steps wherein the two substrates are pre-processed. For example, the photovoltaic coating can be deposited onto one of the substrates by any known technique, such as sputtering. As another example, one of the substrates 11, 12 may be pre-processed by forming at least one opening 18 in it, preferably in the substrate that does not have the photovoltaic coating 42.

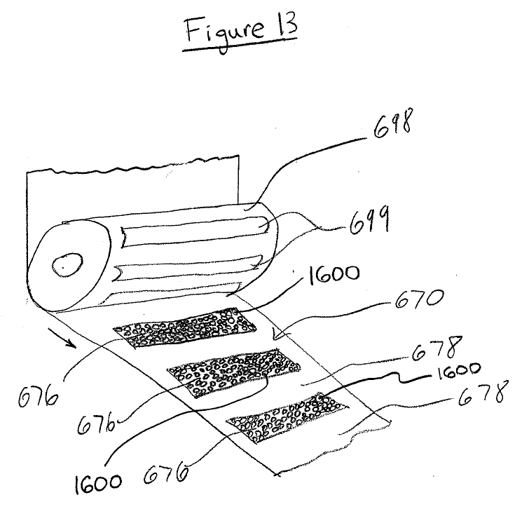

Some preferred embodiments include applying a retention film 660 over the photovoltaic coating 42. In certain embodiments, this is done before the first seal 14 is applied. As shown schematically, in FIG. 12, the retention film 660 can be provided in a roll 690, optionally orientated with a generally horizontal axis of rotation. The substrate bearing the photovoltaic coating can be conveyed along an automated assembly line (optionally using rollers 694) until reaching a station for applying retention film. While FIG. 12 depicts an assembly line for conveying the substrates generally vertically, a horizontal system can alternatively be used. Referring to the center image in FIG. 12, the retention film can be pulled downward from the roll so as to cover the photovoltaic coating 42, and the film can be cut horizontally by a blade moveable automatically along a generally horizontal cut line 696 to separate it from the roll. The retention film 42 can be adhered to the photovoltaic coating 42 by pressing a pressure-sensitive adhesive on one side of the retention film against the substrate surface that bears the photovoltaic coating. In some embodiments, the method includes cutting an opening in the retention film 660 such that when the two substrates 11, 12 are assembled together, the opening in the retention film 660 is at least generally or substantially aligned with an opening in the other substrate, as is perhaps best appreciated by referring to FIG. 3A (wherein the dashed horizontal lines show both openings).

In some embodiments, the method may further comprise providing a desiccant in the gas space 200. Depending upon the type of desiccant used, the desiccant may be applied at various times during the assembly process and in various ways.

In some embodiments, as shown schematically in FIG. 13, granular or “beaded” desiccant is introduced into a rotating structure (e.g., a drum) 698, which is shown having a horizontal axis of rotation, although this is not strictly required. The drum has a series of openings 699 through which desiccant inside the drum passes (during rotation of the drum) so as to apply desiccant in a pattern onto an adhesive covered surface of a film. The resulting desiccant-carrying film can be cut into sheets of the desired size and adhered to the retention film. This can be done after applying the retention film and before joining the two substrates together. The desiccant-free areas 678 of the film 670 will have exposed adhesive and thus can be adhered to the retention film without any additional fastening means.

Referring to FIG. 10, an assembly 10 is shown with a first seal 14 in place and recessed from the peripheral edges of the substrates 11, 12, so as to define a peripheral channel 130. A second seal 15 is then deposited into the channel 130, optionally in the manner described above. If the material forming the second seal 15 requires curing, then it will be allowed to cure after being deposited.

In methods involving the nozzle 600 described above, the secondary sealant can be pumped through the nozzle as the nozzle is conveyed (e.g., by an automated gantry) around the periphery of the assembly. The material will exit the nozzle through the angled outlet to deposit the second seal material against the first seal 14 in a manner that significantly reduces or eliminates air space between the two seals 14, 15. In some embodiments, the angled outlet 604 deposits material while being oriented so as to face generally away from the nozzle's direction of travel (e.g., as the nozzle is conveyed around the peripheral channel).

In some embodiments, the method may include routing lead wires out from the gas space 200 through an opening 18 in the second substrate 12.

After both substrates 11, 12 have been joined together by the seal system 13, for those embodiments that include one or more openings, (e.g., openings 18 in substrate 12 (FIG. 3) or a seal opening 19 in the seal system 13), the opening(s) can optionally be used to perform secondary operations. Such secondary operations may include dispensing a desiccant into the gas space 200 and coupling lead wires to bus bars 706 (FIG. 7A). According to some embodiments, the coupled lead wires are routed out from the gas space 200 through opening(s) 18, but according to alternate embodiments, the coupled lead wires are routed out through the seal system 13 or through seal openings 19 in the seal system 13, (FIG. 7B). When provided, the opening(s) 18, 19 may have a diameter of between approximately ¼ inch and approximately 1.5 inches, e.g., to accommodate secondary operations. In a further method step for such embodiments, one or more openings are sealed off with a potting material. Examples of suitable potting materials include, without limitation, silyl-containing polyacrylate polymer, XMAP™ polymer, polyurethane, epoxy, polyisobutylene, and any low MVTR material; according to some embodiments, the same material that forms the first seal 14 or the second seal 15 is used for the potting material.

One exemplary automated production system for producing the present assembly 10 applies PIB as the first seal, silicone as the second seal, polyethylene film (with pressure-sensitive acrylic adhesive on one side) having a thickness of about 0.003-0.005 inch as the retention film, with the gas space being filled with air and having a thickness of about 0.04 to 0.08. The production system and its method of use can optionally employ one or more of the following features/steps: 1. PIB: a. gear pump drum unloader with closed loop pressure control; b. positive displacement closed loop metering pump directly connected to dispensing nozzle; c. closed loop heated drum unloader and hose delivery system; d. closed loop metering system is electronically geared to the nozzle velocity; e. gantry automatically detects variations in glass position and size; f. position of the primary seal bead is dynamically adjusted relative to the edge determined by method e; g. dispensing nozzle has an integrated shutoff valve to minimize material left in the nozzle cavity (helps to eliminate leftover sealing material in the unit; h. holding system of the primary seal machine accurately holds the piece of glass on a flat plane while the primary seal is applied. 2. Assemble and Merge System: a. front and back glass are accurately assembled and aligned to known datum points using a high speed positioning system. 3. Press: a. pressing system utilizes multiple forcing units to apply even pressure over the whole units; b. positive stops are used to ensure that each unit is pressed to same overall thickness while maintaining glass positioning from method 2. 4. Silicone: a. gear pump drum unloader with closed loop pressure control; b. positive displacement closed loop metering pump directly connected to dispensing nozzle; c. closed loop heated drum unloader and hose delivery system; d. closed loop metering system is electronically geared to the nozzle velocity; e. gantry automatically detects variations in glass position and size; f. position of the secondary seal is dynamically adjusted relative to the edge determined by method e; g. precision dispensing nozzle capable of applying the secondary seal with zero air gap between the primary and secondary sealing materials; h. machine is capable of accurately dispensing the secondary seal material such that no excess sealing material protrudes from the unit; i. vacuum carriage conveying systems allows the machine to accurately position glass without restricting nozzle access to any edge of the glass; j. holding system of the secondary seal machine accurately holds the assembled panel on a flat plane while the secondary seal is applied.

Thus, the invention provides assemblies, and methods for producing assemblies, that in some embodiments have a retention film of the nature described above (e.g., of the thicknesses, materials, retention capabilities, and/or adhesive type described above). In other embodiments, the assemblies and methods have a thin gas space of the nature described above (e.g., of the noted thickness, arrangement, area, etc.). In still other embodiments, the assemblies and methods have a peripheral seal system of the nature described above (e.g., of the noted compositions, location, properties, and/or relative dimensions). In all of these embodiments, the assembly has a photovoltaic coating, as has already been described, and can optionally include a desiccant in accordance with the different desiccant options described above. In some embodiments, the assembly has both a retention film and a gas space of the nature described, or the assembly has both a retention film and a seal system of the nature described, or the assembly has both a gas space and a seal system of the nature described. Still further, some embodiments provide the assembly with a retention film, a gas space, and a seal system of the nature described. In these combination embodiments, the preferred and optional features, characteristics, configurations, and properties of the retention film, gas space, and seal system can be in accordance with any of the embodiments described above or shown in the drawings.

In the foregoing detailed description, the invention has been described with reference to specific embodiments. However, it may be appreciated that various modifications and changes can be made without departing from the scope of the invention.

What is claimed is:

1. A photovoltaic glazing assembly, comprising:
a first substrate formed of a light transmitting material, and a second substrate, each of the first and second substrates having first and second major surfaces, each second surface having a central region and a periphery and the second surfaces facing each other, said second surfaces being generally parallel;
a temperature-sensitive photovoltaic coating over at least the central region of the second surface of the first substrate or the second substrate, the photovoltaic coating being characterized by a photovoltaic efficiency that decreases with increasing temperature;
a gas space located between the first and second substrates and having a thickness T of between 0.01 inch and 0.095 inch to facilitate heat transfer across the gas space so as to restrain loss of photovoltaic efficiency due to temperature increases of the photovoltaic coating, the gas space being the glazing assembly's only interpane space; and
a peripheral seal system located between the first and second substrates and comprising contiguous first and second seals, each connecting the first and second substrates together along their peripheries, the first seal having a width W₁ and a thickness t that provide a W₁/t ratio of at least 2.

2. The assembly of claim 1, wherein the thickness T of the gas space is between 0.01 inch and 0.085 inch.

3. The assembly of claim 1, wherein the thickness T of the gas space is between 0.01 inch and 0.08 inch.

4. The assembly of claim 1, wherein the W₁/t ratio is at least 3.

5. The assembly of claim 1, wherein the W₁/t ratio is at least 4.

6. The assembly of claim 1, wherein the peripheral seal system between the first and second substrates consists essentially of the first and second seals, and the first and second seals both comprise polymer.

7. The assembly of claim 1, wherein the substrate bearing the photovoltaic coating defines a #1 surface through which solar radiation is to first enter the photovoltaic glazing assembly.

8. The assembly of claim 1, wherein the gas space has an area A, measured parallel to said second surfaces, that is selected in conjunction with the thickness T of the gas space to provide a T/A ratio of less than about 2.6×10⁻⁴/inch.

9. The glazing of claim 7 wherein the T/A ratio is less than about 8.7×10⁻⁵/inch.

10. The assembly of claim 1 wherein the second seal has a thickness t that is at least substantially equal to the thickness t of the first seal, the second seal having a width W₂ that is selected in conjunction with the thickness t of the second seal to provide a W₂/t ratio for the second seal of at least 2.

11. The of claim 1 wherein the W₂/t ratio for the second seal is at least 2.5.

12. The assembly of claim 1, wherein the first seal is formed of an extrudable material having a moisture vapor transmission rate that does not exceed approximately 5 g mm/m²/day at 38° C. and 100% relative humidity.

13. The assembly of claim 1, wherein the first seal comprises a butyl sealant material, and the second seal comprises a material selected from the group consisting of silicone, polysulfide, and polyurethane.

14. The assembly of claim 1, wherein the second seal comprises a silyl containing polyacrylate polymer.

15. The assembly of claim 14, wherein the silyl containing polyacrylate polymer comprises a silyl terminated acrylic polymer.

16. The assembly of claim 1, including a retention film over the photovoltaic coating, the retention film comprising a flexible and electrically non-conductive film and having a thickness of less than 0.009 inch.

17. The assembly of claim 16, wherein the thickness of the retention film is less than 0.006 inch.

18. The assembly of claim 16, wherein the retention film is both adhered directly to the photovoltaic coating and exposed to the gas space.

19. The assembly of claim 16, wherein the retention film is adhered to the photovoltaic coating by a pressure-sensitive adhesive.

20. The assembly of claim 16, wherein the periphery of the second surface of the substrate bearing the photovoltaic coating is devoid of both the retention film and the photovoltaic coating.

21. The assembly of claim 16, wherein the photovoltaic coating is on the second surface of the first substrate, an opening is formed in the second substrate, and an opening is formed in the retention film, said openings in the retention film and the second substrate being at least generally aligned.

22. The assembly of claim 1, wherein the photovoltaic glazing assembly is devoid of laminated glass.

23. The assembly of claim 1, wherein the photovoltaic glazing assembly is devoid of contact between the photovoltaic coating and EVA or PVB.

24. The assembly of claim 1, wherein a desiccant material is in communication with the gas space.

25. A method for making a photovoltaic glazing assembly, the method comprising:
providing a first substrate and a second substrate, the first and second substrates each having first and second major surfaces, said second surfaces each having a central region and a periphery, at least one of the substrates being transparent;
providing a temperature-sensitive photovoltaic coating on at least the central region of the second surface of the first or second substrate, the photovoltaic coating being characterized by a photovoltaic efficiency that decreases with increasing temperature;
applying a first seal to the periphery of at least one of the substrates, such that the first seal is spaced from the edge of that substrate;
bringing the first and second substrates together in an opposed relationship such that the first seal is between the peripheries of the second surfaces of the first and second substrates, and applying pressure until a gas space between the first and second substrates has a thickness T of less than 0.095 inch so as to facilitate heat transfer across the gas space and thereby restrain loss of photovoltaic efficiency due to temperature increases of the photovoltaic coating, and thereafter
applying a second seal into a peripheral channel defined collectively by the first seal and peripheral regions of the second surfaces of the first and second substrates, the second seal being contiguous to the first seal such that there are substantially no air spaces between the first and second seals.

26. The method of claim 25, wherein the first seal when initially applied has a generally half-round configuration in cross section, and wherein sufficient pressure is applied to conform the first seal to both substrates and to give it a width W₁ of at least 0.2 inch and a thickness t of less than 0.09 inch.

27. The method of claim 25, wherein the step of applying pressure deforms the first seal by reducing a thickness t and increasing a width W₁ of the first seal, and wherein upon reaching the thickness t desired for the first seal the method includes maintaining said pressure so as to hold the two substrates together for a period of time sufficient to allow the first seal to complete its deformation.

28. The method of claim 25, wherein sufficient pressure is applied to set the thickness T of the gas space at between 0.01 inch and 0.085 inch.

29. The method of claim 28, wherein sufficient pressure is applied to set the thickness T of the gas space at between 0.01 inch and 0.08 inch.

30. The method of claim 25, wherein the contiguous first and second seals together form a seal system having a width W₃ and a thickness t selected to provide a W₃/t ratio of greater than 4.

31. The method of claim 30, wherein the W₃/t ratio is greater than 6.

32. The method of claim 25, wherein the method includes providing a retention film having a surface bearing a pressure-sensitive adhesive, and securing the retention film to the photovoltaic coating by adhering the pressure-sensitive adhesive to the photovoltaic coating, the retention film comprising a flexible and electrically non-conductive film and having a thickness of less than 0.006 inch, the retention film being exposed to the gas space in the resulting photovoltaic glazing assembly.

33. A photovoltaic glazing assembly, comprising:
first and second substrates each having first and second major surfaces, each second surface having a central region and a periphery, the second surfaces facing each other, at least one of the first and second substrates being formed of a light transmitting material;
a temperature-sensitive photovoltaic coating over at least the central region of the second surface of the first substrate or the second substrate, the photovoltaic coating being characterized by a photovoltaic efficiency that decreases with increasing temperature;
a flexible and electrically non-conductive retention film over the photovoltaic coating, the retention film having a thickness of less than 0.009 inch and yet having a tear strength combined with a flexibility that hold the photovoltaic coating together with the underlying substrate in case that substrate is fractured;
a gas space located between the first and second substrates, the gas space having a thickness T of between 0.01 inch and 0.09 inch to facilitate heat transfer across the gas space so as to restrain loss of photovoltaic efficiency due to temperature increases of the photovoltaic coating, wherein an exposed surface of the retention film bounds the gas space; and
a seal system between the first and second substrates and joining the first and second substrates to each other along their peripheries.

34. The assembly of claim 33, wherein the thickness of the retention film is between 0.001 inch and 0.006 inch.

35. The assembly of claim 33, wherein the retention film is adhered to the photovoltaic coating by a pressure-sensitive adhesive.

36. The assembly of claim 33, wherein the retention film is both adhered directly to the photovoltaic coating and exposed to the gas space.

37. The assembly of claim 33, wherein the periphery of the second surface of the substrate bearing the photovoltaic coating is devoid of both the retention film and the photovoltaic coating.

38. The assembly of claim 33, wherein the retention film comprises a material selected from the group consisting of polyethylene, polypropylene, polyester, and PVC.

39. The assembly of claim 33, wherein a desiccant material is in communication with the gas space, the desiccant material being affixed to a film that is adhered to the retention film.

40. The assembly of claim 33, wherein the thickness T of the gas space is between 0.01 inch and 0.085 inch.

41. A method for making a photovoltaic glazing assembly, the method comprising:
providing a first substrate and a second substrate, the first and second substrates each having first and second major surfaces, said second surfaces each having a central region and a periphery, at least one of the substrates being transparent, and wherein a photovoltaic coating is on at least the central region of the second surface of the first or second substrate;
applying a ribbon comprising side-by-side first and second seals to the periphery of at least one of said second surfaces, such that when initially applied the ribbon has a thickness t that is greater adjacent to a midpoint of the ribbon than adjacent to sides of the ribbon;
bringing the first and second substrates together in an opposed relationship such that the ribbon is between the peripheries of the second surfaces of the first and second substrates, and applying pressure so as to move the first and second substrates closer together until the thickness t of the ribbon is at least substantially uniform from the midpoint to the sides of the ribbon.

42. The method of claim 41, wherein when the ribbon is applied the side-by-side first and seal seals are contiguous and have substantially no air pockets between them.

43. The method of claim 41, wherein the midpoint of the ribbon is adjacent to an interface between the first and second seals.

44. The method of claim 43, wherein the thickness t of the ribbon is greatest adjacent to the interface between the first and second seals.

45. The method of claim 41, wherein the ribbon when initially applied has a tapered configuration characterized by the thickness of the ribbon being greatest adjacent to the midpoint and least adjacent to one or both sides of the ribbon.

46. The method of claim 45, wherein the tapered configuration involves the taper extending at least substantially entirely between the midpoint and each side of the ribbon.

47. The method of claim 45, wherein the tapered configuration includes an exposed top face defined by slanted surfaces that are substantially planar.

48. The method of claim 41, wherein at least one of the substrates is a glass sheet, the first seal comprises a butyl sealant material, and the second seal comprises a material selected from the group consisting of silicone, polysulfide, and polyurethane.

49. The method of claim 41, wherein after the pressure application step there are substantially no air pockets between the ribbon and the first and second substrates.

50. The method of claim 41, wherein after the pressure application step an exterior side of the ribbon is at least generally flush with edges of the first and second substrates.

51. The method of claim 41, wherein when the ribbon is initially applied it is spaced inwardly from the edge of the underlying substrate.

52. A photovoltaic glazing assembly, comprising:
first and second substrates each having first and second major surfaces, each second surface having a central region and a periphery, the second surfaces facing each other, at least one of the first and second substrates being formed of a light transmitting material;
a photovoltaic coating over at least the central region of the second surface of the first substrate or the second substrate;
a flexible and electrically non-conductive retention film over the photovoltaic coating, the retention film having a thickness of less than 0.006 inch and yet having a tear strength combined with a flexibility that hold the photovoltaic coating together with the underlying substrate in case that substrate is fractured;
a gas space located between the first and second substrates, wherein an exposed surface of the retention film bounds the gas space; and
a seal system between the first and second substrates and joining the first and second substrates to each other along their peripheries.

53. The assembly of claim 52, wherein the thickness of the retention film is less than 0.005 inch.

54. The assembly of claim 52, wherein the gas space has a thickness T of between 0.01 inch and 0.09 inch.
